(19) United States
(12) Patent Application Publication
(10) Pub. No.: US 2026/0262249 A1
(43) Pub. Date: Sep. 3, 2026

(54) SEMICONDUCTOR DEVICE, POWER CONVERTER, AND METHOD OF MANUFACTURING SEMICONDUCTOR DEVICE

(71) Applicant: Mitsubishi Electric Corporation, Chiyoda-ku, Tokyo (JP)

(72) Inventors: Yoshitaka KIMURA, Tokyo (JP); Munenori IKEDA, Tokyo (JP); Kazunari NAKATA, Tokyo (JP); Keiji BEPPU, Tokyo (JP); Masaya NONOMURA, Tokyo (JP); Fumitoshi YAMAMOTO, Tokyo (JP); Michiaki TAKENAKA, Tokyo (JP)

(73) Assignee: Mitsubishi Electric Corporation, Chiyoda-ku, Tokyo (JP)

(21) Appl. No.: 19/162,893

(22) PCT Filed: Apr. 26, 2024
(86) PCT No.: PCT/JP2024/016454

§ 371 Date: Sep. 5, 2025

(30) Foreign Application Priority Data
May 15, 2023 (JP) 2023-079985

(51) Int. Cl. H10D 30/66; H02M 1/00; H10D 30/01; H10D 62/10; H10D 62/832; H10D 64/27

(52) U.S. Cl. CPC H10D 30/668; H02M 1/0054; H10D 30/0297; H10D 30/665; H10D 62/8325; H10D 64/518; H10D 62/102

(57) ABSTRACT

Electrode melting is suppressed even when a high voltage is applied. A semiconductor device according to a technique disclosed in the specification of the present application includes at least one first groove formed from the upper surface of a base region to the interior of a drift layer in a cell area, a second groove formed from the upper surface of the base region to the interior of the drift layer in a termination area that surrounds the cell area in plan view, a source region, a source electrode, and a drain electrode. The first gate electrode and the second gate electrode are electrically connected to each other. The second groove is deeper than the first groove.

### TECHNICAL FIELD

A technique disclosed in the specification of the present application relates to semiconductor technology.

### BACKGROUND ART

Semiconductor devices using a silicon carbide (SiC) substrate (hereinafter referred to as “SiC semiconductor devices”) are superior in dielectric strength and heat resistance to semiconductor devices using a silicon (Si) substrate (hereinafter referred to as “Si semiconductor devices”).

To enable semiconductor devices to withstand high voltages, reduce losses, or be used in high-temperature environments, SiC semiconductor devices have conventionally been applied to power semiconductor devices such as metal-oxide-semiconductor field-effect transistors (i.e., MOSFETs) or insulated gate bipolar transistors (i.e., IGBTs).

SiC has higher breakdown field strength than Si. Thus, SiC semiconductor devices can make a withstand voltage layer (drift layer) thinner than Si semiconductor devices to achieve the same dielectric strength. Besides, SiC semiconductor devices can have a higher amount of impurity doping in the withstand voltage layer than Si semiconductor devices.

For these reasons, SiC semiconductor devices have a significantly lower on-state resistance than Si semiconductor devices. For example, a SiC-MOSFET with a dielectric strength of higher than or equal to 1 kV and lower than or equal to 1.2 kV has an on-state resistance of lower than or equal to 5 mΩcm² that is less than or equal to half the on-state resistance of a Si-MOSFET or a Si-IGBT with the same dielectric strength.

Due to a reduction in manufacturing costs, improvements in process technology, and other performance improvements, it is expected that most of Si-IGBTs serving as inverter parts will be replaced by SiC semiconductor devices in the future.

In order to reduce losses during the application of current to SiC semiconductor devices, trench-gate type SiC-MOSFETs or SiC-IGBTs are currently being developed.

In the trench-gate type SiC-MOSFETs or SiC-IGBTs, however, electric fields will be concentrated at the corners of trench bottoms in the cell area, causing a breakdown in gate insulating films.

Regarding this, for example, Patent Document 1 discloses a method of relieving electric fields at trench bottoms by forming a p-type diffusion layer to surround the trench bottoms. This method can suppress electric field concentration at trench bottoms, thereby reducing the occurrence of a breakdown in gate insulating films.

### PRIOR ART DOCUMENT

### Patent Document

Patent Document 1: Japanese Patent Application Laid-Open No. 2007-173319

### SUMMARY

### Problem to be Solved by the Invention

In trench-gate type SiC-MOSFETs or SiC-IGBTs, when switching operations are performed under high current and high voltage conditions, breakdowns of gate insulating films occur at the points of electric field concentration at trench bottoms in the cell area, and energy is concentrated at the breakdown points, generating heat and causing electrode melting. This electrode melting can cause molten metal to adhere to a measuring device, necessitating maintenance of the measuring device and making it difficult to measure other chips.

The structure disclosed in Patent Document 1 makes the gate insulating films less susceptible to breakdown, but since electric fields are concentrated at trench bottoms in the cell area, if a chip is broken, energy is concentrated at the broken point, generating heat and causing electrode melting.

The technique disclosed in the specification of the present application has been made in light of issues as described above, and can suppress electrode melting even when a high voltage is applied.

### Means to Solve the Problem

A semiconductor device according to a first aspect of the technique disclosed in the specification of the present application includes a silicon carbide (SiC) substrate of a first conductivity type, a drift layer of the first conductivity type formed on an upper surface of the SiC substrate, a base region of a second conductivity type formed in a surface layer of the drift layer, the second conductivity type being different from the first conductivity type, at least one first groove formed from an upper surface of the base region to an interior of the drift layer in a cell area, a second groove formed from the upper surface of the base region to the interior of the drift layer in a termination area that surrounds the cell area in plan view, a source region of the first conductivity type formed partially in a surface layer of the base region to sandwich the first groove, a first gate electrode formed inside the first groove and surrounded by a gate insulating film, at least one second gate electrode formed inside the second groove and surrounded by a gate insulating film, interlayer insulation films formed to cover the first gate electrode and the second gate electrode, a source electrode formed in contact with the source region, and a drain electrode formed on a lower surface of the SiC substrate that is a surface on a side opposite to the upper surface of the SiC substrate. The first gate electrode and the second gate electrode are electrically connected to each other. The second groove is deeper than the first groove.

### Effects of the Invention

According to at least the first aspect of the technique disclosed in the specification of the present application, when a high voltage is applied, the electric field at the bottom of the second groove in the termination area becomes greater than the electric field at the bottom of the first groove in the cell area. As a result, a breakdown of the gate insulating film is more likely to occur in the termination area and is relatively less likely to occur in the cell area where a large current flows. This suppresses heat generation at the breakdown point, and as a result, suppresses electrode melting.

The object, features, aspects, and advantages relating to the technique disclosed in the specification of the present application will become more apparent from the following detailed description and the accompanying drawings.

### BRIEF DESCRIPTION OF DRAWINGS

FIG. 1 is a sectional view showing an example of a configuration of a SiC semiconductor device according to an embodiment.

FIG. 2 is a flowchart showing an example of a process of manufacturing the SiC semiconductor device according to the embodiment.

FIG. 3 is a sectional view showing an example of the process of manufacturing the SiC semiconductor device according to the embodiment.

FIG. 4 is a sectional view showing an example of the process of manufacturing the SiC semiconductor device according to the embodiment.

FIG. 5 is a sectional view showing an example of the process of manufacturing the SiC semiconductor device according to the embodiment.

FIG. 6 is a sectional view showing an example of the process of manufacturing the SiC semiconductor device according to the embodiment.

FIG. 7 is a sectional view showing an example of the process of manufacturing the SiC semiconductor device according to the embodiment.

FIG. 8 is a sectional view showing an example of the process of manufacturing the SiC semiconductor device according to the embodiment.

FIG. 9 is a sectional view showing an example of the process of manufacturing the SiC semiconductor device according to the embodiment.

FIG. 10 is a sectional view showing an example of the process of manufacturing the SiC semiconductor device according to the embodiment.

FIG. 11 is a sectional view showing an example of the process of manufacturing the SiC semiconductor device according to the embodiment.

FIG. 12 is a sectional view showing an example of the process of manufacturing the SiC semiconductor device according to the embodiment.

FIG. 13 is a sectional view showing an example of the process of manufacturing the SiC semiconductor device according to the embodiment.

FIG. 14 is a sectional view showing an example of the process of manufacturing the SiC semiconductor device according to the embodiment.

FIG. 15 is a sectional view schematically showing an example of current paths when current flows through the SiC semiconductor device according to the embodiment.

FIG. 16 is a sectional view showing an example of the configuration of the SiC semiconductor device according to the embodiment.

FIG. 17 is a schematic diagram showing electric field distributions at a section B-B′ and a section C-C′ in FIG. 16.

FIG. 18 is a sectional view showing an example of the process of manufacturing a SiC semiconductor device according to another embodiment.

FIG. 19 is a sectional view showing an example of the process of manufacturing a SiC semiconductor device according to yet another embodiment.

FIG. 20 is a sectional view showing an example of a configuration of the SiC semiconductor device according to the embodiment.

FIG. 21 is a sectional view showing an example of the configuration of the SiC semiconductor device according to the embodiment.

FIG. 22 is a diagram that is a combination of a plan view and a sectional view showing an example of the process of manufacturing a SiC semiconductor device according to yet another embodiment.

FIG. 23 is a sectional view showing an example of a configuration of the SiC semiconductor device according to the embodiment.

FIG. 24 is a sectional view showing an example of the process of manufacturing a SiC semiconductor device according to yet another embodiment.

FIG. 25 is a sectional view showing an example of a configuration of the SiC semiconductor device according to the embodiment.

FIG. 26 is a sectional view showing an example of the process of manufacturing a SiC semiconductor device according to yet another embodiment.

FIG. 27 is a sectional view showing an example of a configuration of the SiC semiconductor device according to the embodiment.

FIG. 28 is a diagram conceptually showing an example of a configuration of a power conversion system that includes a power converter according to an embodiment.

### DESCRIPTION OF EMBODIMENTS

Embodiments will be described hereinafter with reference to the accompanied drawings. Although the following embodiments describe detailed features or the like in order to explain technology, these features are merely examples, and not all of them are necessarily required for the embodiments to be implemented.

Note that the drawings are shown schematically, and for the sake of convenience, configurations may be omitted or simplified in the drawings as appropriate. The size and relative positions of constituent elements or the like shown in the different drawings are not necessarily precisely depicted and may be changed as appropriate. In drawings other than sectional views, such as plan views, hatching may be used to facilitate understanding of the contents of the embodiments.

In the following description, identical constituent elements are illustrated with the same reference signs, and the names and functions of these constituent elements are also the same. Therefore, detailed descriptions of these constituent elements may be omitted to avoid duplication.

In the descriptions given in the specification of the present application, unless otherwise specified, expressions such as “comprise,” “include,” or “have” a certain constituent element are not exclusive expressions that exclude the presence of other constituent elements.

In the descriptions given in the specification of the present application, even though ordinal numbers such as “first” or “second” are used, these terms are used only as a matter of convenience to facilitate understanding of the contents of the embodiments, and the contents of the embodiments are not limited to any ordering that may occur due to these ordinal numbers.

In the descriptions given in the specification of the present application, even though terms such as “upper,” “lower,” “left,” “right,” “side,” “bottom,” “front,” and “rear” may be used to indicate a specific position or direction, these terms are used only as a matter of convenience to facilitate understanding of the contents of the embodiments and have no bearing on the locations or orientations when the embodiments are actually implemented.

In the descriptions given in the specification of the present application, expressions such as the “upper surface of . . . ” or the “lower surface of . . . ” include not only the upper surface or lower surface itself of a target constituent element, but also a state in which another constituent element is formed on the upper or lower surface of the target constituent element. That is, for example, the expression “B provided on the upper surface of A” does not prevent the possibility of another constituent element C being interposed between A and B.

### First Embodiment

A semiconductor device according to the present embodiment and a method of manufacturing the semiconductor device will be described hereinafter.

### Configuration of Semiconductor Device

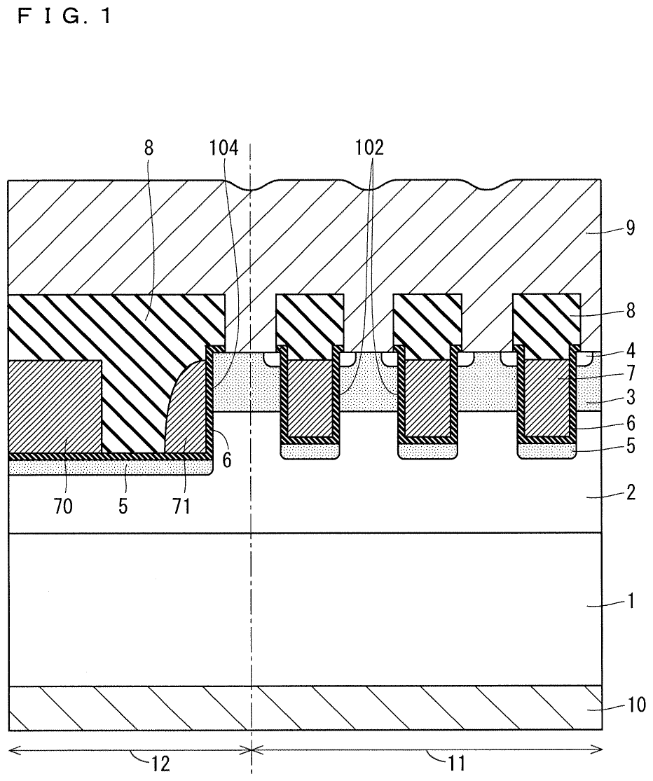

FIG. 1 is a sectional view showing an example of a configuration of a SiC semiconductor device according to the present embodiment. The SiC semiconductor device shown in FIG. 1 is one example of a SiC-n MOSFET having a trench gate structure, and a cell area 11 and a termination area 12 that serve as the main part of the SiC semiconductor device are shown in the drawing.

The following describes the SiC-n MOSFET, but a SiC-p MOSFET or a SiC-IGBT is also applicable. An overall configuration of the SiC semiconductor device is a continuous configuration of cell areas 11, which serve as the main part shown in FIG. 1. The larger the current flowing through the SiC semiconductor device, the larger is the proportion of the cell areas 11 in the overall configuration of the SiC semiconductor device.

As shown in FIG. 1, the SiC semiconductor device includes an n-type SiC substrate 1, an n-type drift layer 2 formed on the upper surface of the n-type SiC substrate 1, a p-type base region 3 formed in a surface layer of the n-type drift layer 2, a plurality of grooves 102 formed from the upper surface of the p-type base region 3 to the interior of the n-type drift layer 2 in the cell area 11, a groove 104 formed from the upper surface of the p-type base region 3 to the interior of the n-type drift layer 2 in the termination area 12 that surrounds the cell area 11 in plan view, a p-type base region 5 formed on the bottom surfaces of the grooves 102 that face the n-type drift layer 2, a p-type base region 5 formed on the bottom surface of the groove 104 that faces the n-type drift layer 2, an n-type source region 4 formed partially in the surface layer of the p-type base region 3 to sandwich the grooves 102, a gate insulating film 6 formed inside the grooves 102 in contact with the side and bottom surfaces of the grooves 102, formed in contact with part of the upper surface of the p-type base region 3, and formed inside the groove 104 in contact with the side and bottom surfaces of the groove 104, a gate electrode 7 formed inside the grooves 102 and surrounded by the gate insulating film 6, a gate electrode 70 formed inside the groove 104 and surrounded by the gate insulating film 6, a gate electrode 71 formed inside the groove 104 to be spaced from the gate electrode 70 and surrounded by the gate insulating film 6, an interlayer insulation film 8 formed to cover the gate electrodes 7, 70, and 71, a source electrode 9 formed to cover the interlayer insulation film 8, the p-type base region 3, and the n-type source region 4, and a drain electrode 10 formed on the lower surface of the n-type SiC substrate 1 (the surface on the side opposite to the upper surface of the n-type SiC substrate).

Here, the groove 104 is formed deeper than the grooves 102.

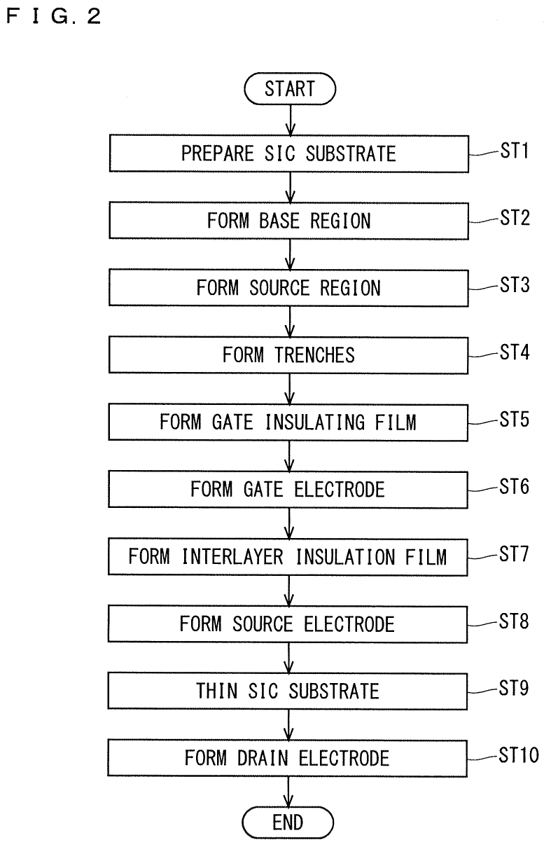

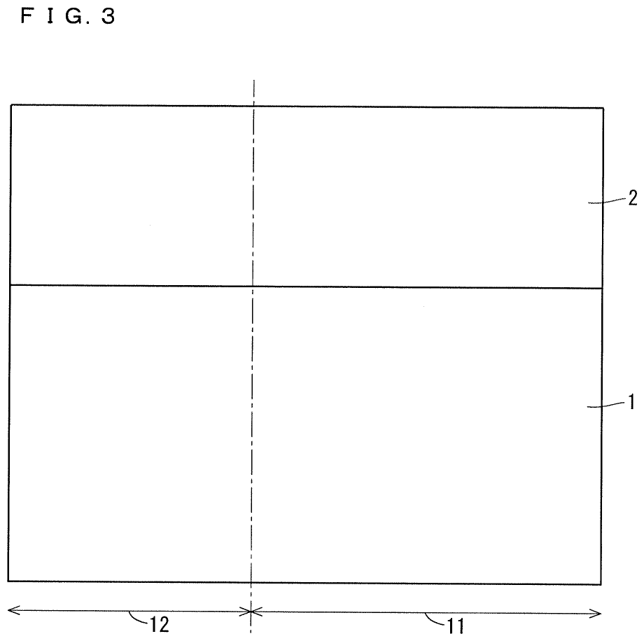

FIG. 2 is a flowchart showing an example of the process of manufacturing the SiC semiconductor device according to the present embodiment. FIGS. 3 to 14 are sectional views showing an example of the process of manufacturing the SiC semiconductor device according to the embodiment. The SiC semiconductor device shown in FIG. 1 is manufactured in accordance with the manufacturing process shown in FIG. 2.

Firstly, as shown by way of example in FIG. 3, the n-type drift layer 2 formed of n-type SiC is formed as an epitaxial film on a first main surface (hereinafter referred to as the “upper surface”) of the n-type SiC substrate 1 (step ST1).

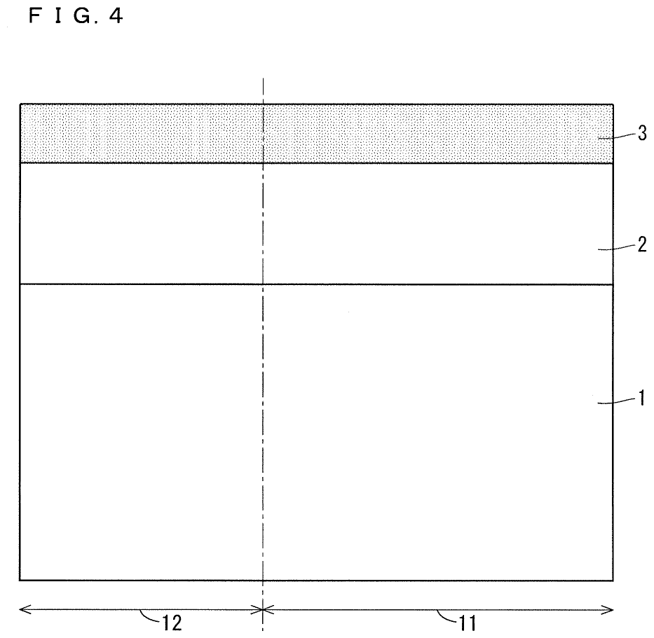

Then, as shown by way of example in FIG. 4, after a mask (not shown) is formed of a resist or the like, p-type impurity ions are implanted into the surface layer of the n-type drift layer 2 to form the p-type base region 3 in the surface layer of the n-type drift layer 2 (step ST2). Examples of the p-type impurity include boron (B) and aluminum (Al).

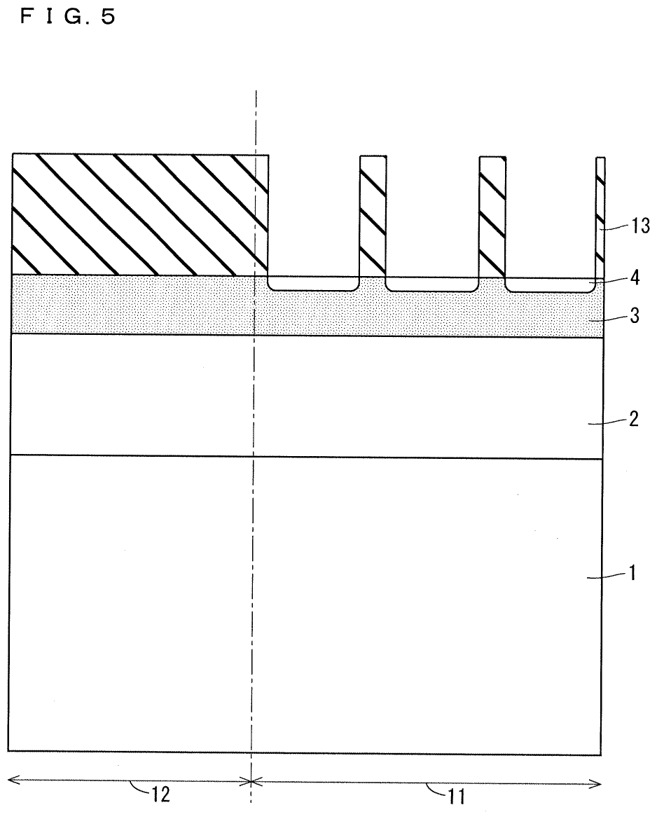

Thereafter, as shown by way of example in FIG. 5, after a mask 13 is formed of a resist on the p-type base region 3, n-type impurity ions are implanted into the surface layer of the p-type base region 3 to form the n-type source region 4 in the surface layer of the p-type base region 3 (step ST3). Examples of the n-type impurity include phosphorus (P) and nitrogen (N).

Thereafter, in order to activate the p-type base region 3 and the n-type source region 4, a SiC wafer is heat-treated at high temperature by heat treatment equipment (not shown here). Then, the p-type ions implanted in the p-type base region 3 and the n-type ions implanted in the n-type source region 4 are activated electrically.

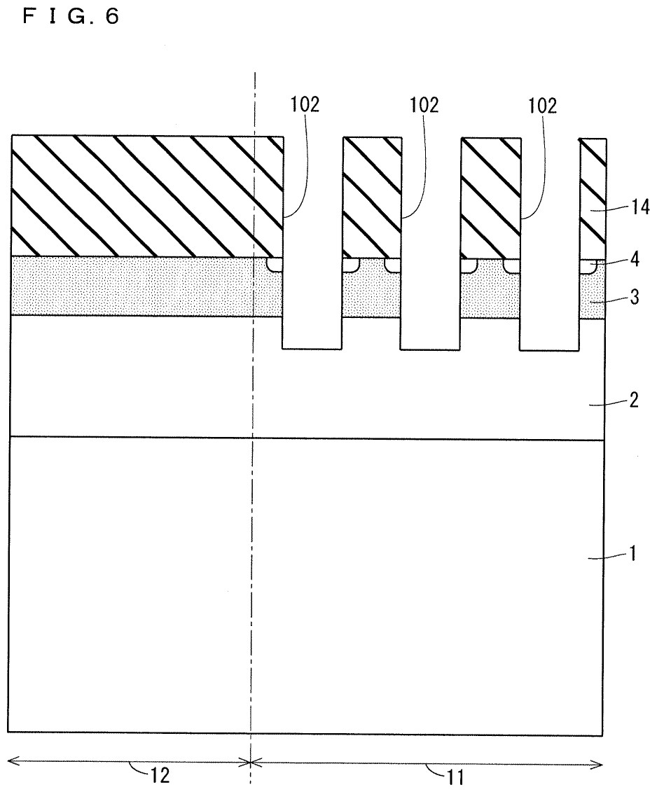

Then, as shown by way of example in FIG. 6, after a mask 14 is formed of a resist for the cell areas, the trench-type grooves 102 in the cell area are formed in the upper surfaces of the p-type base region 3 and the n-type source region 4 by, for example, dry etching using plasma (step ST4).

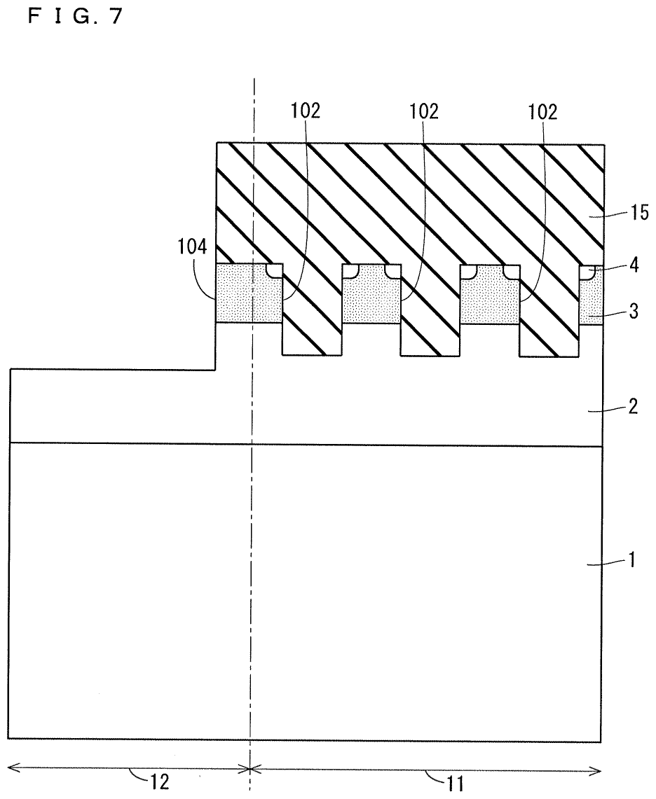

Then, as shown by way of example in FIG. 7, after a mask 15 different from the mask 14 is formed of a resist for the termination area, the trench-type groove 104 in the termination area is formed in the upper surface of the p-type base region 3 by, for example, dry etching using plasma. The groove 104 is formed deeper than the grooves 102.

If it is not possible to provide a mask capable of forming the grooves 102 in the cell area 11 or a mask capable of forming the groove 104 in the termination area 12, deeper grooves may be formed by depositing, for example, an oxide film made from TEOS on the upper surface of the p-type base region 3 shown in FIG. 5 and dry-etching this oxide film by using a resist mask.

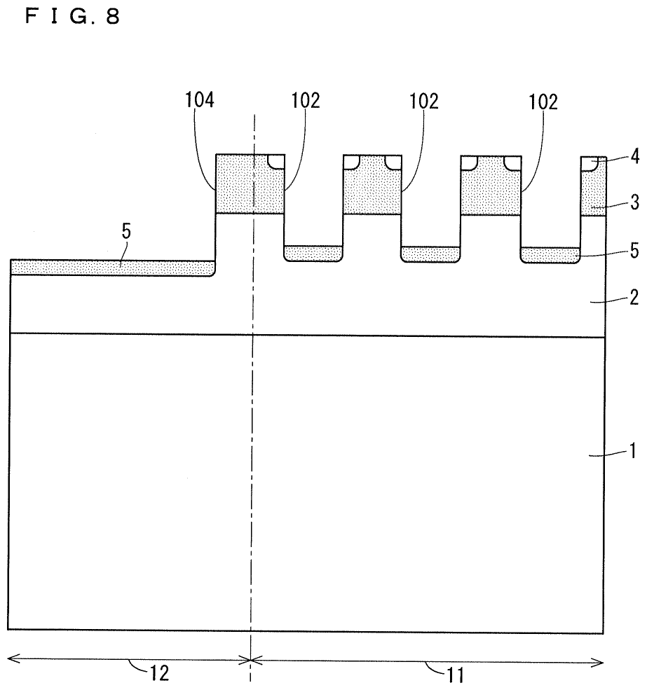

Then, as shown by way of example in FIG. 8, the p-type base region 5 may be formed on the bottoms of the grooves 102 and 104 in order to alleviate electric fields applied to the bottoms of the trench gates. Examples of the p-type impurity include boron (B) and aluminum (Al).

Then, the upper and side surfaces of the structure shown in FIG. 8 are oxidized by thermal oxidation in order to eliminate plasma damage caused during trench gate formation.

To eliminate plasma damage, it is desirable to have a larger amount of oxidation on the upper and side surfaces of the structure shown in FIG. 8. However, this thermal oxidation reduces the impurity layers formed in the surface layer of the n-type drift layer 2 (the p-type base region 3, the n-type source region 4, and the p-type base region 5). Therefore, the surface layer of the n-type drift layer 2 of SiC may be thermally oxidized to a thickness of, for example, greater than or equal to 20 nm and less than or equal to 80 nm and more preferably a thickness of, for example, greater than or equal to 30 nm and less than or equal to 70 nm. By measuring leakage current between the gate electrode 7 and the source electrode 9, the inventors of the present application have confirmed that plasma damage caused during trench gate formation had been eliminated sufficiently by thermal oxidation to the aforementioned thickness.

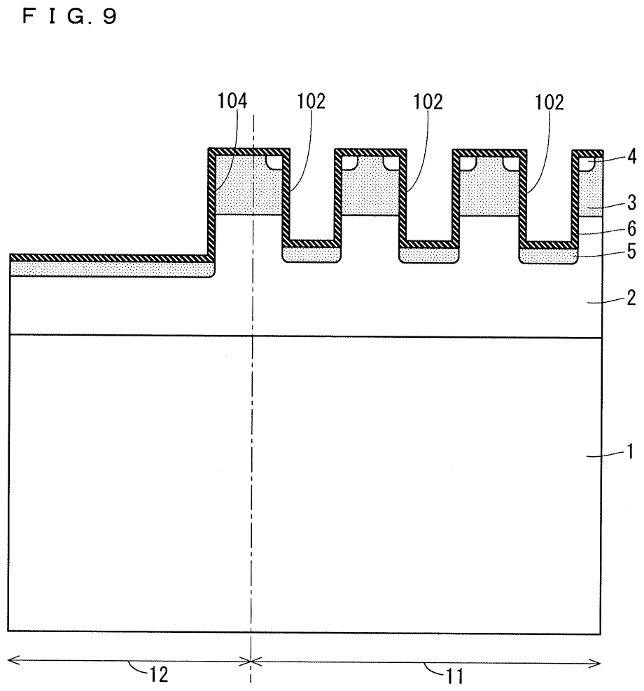

Then, as shown by way of example in FIG. 9, the gate insulating film 6 is formed by a deposition technique such as thermal oxidation or chemical vapor deposition (step ST5).

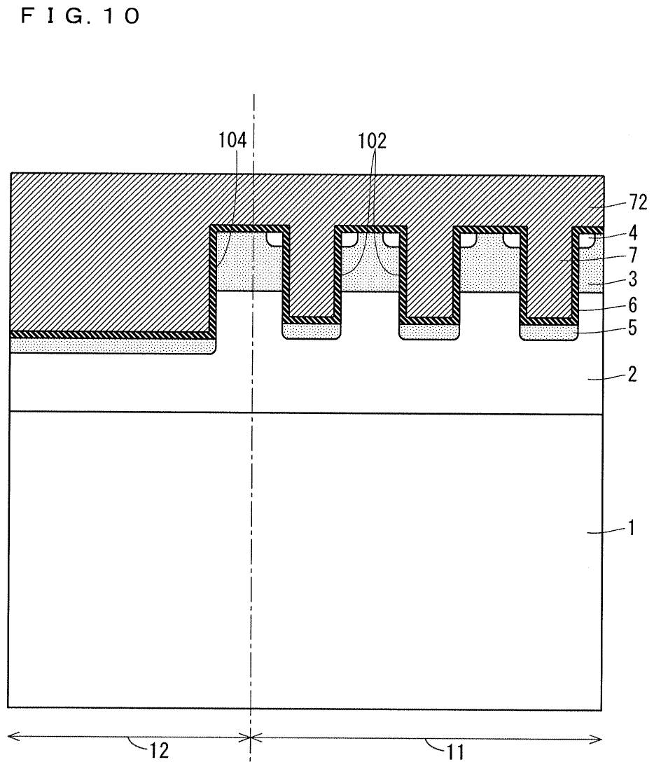

Then, as shown by way of example in FIG. 10, an electrode layer 72 is deposited on the upper surface of the gate insulating film 6 so as to fill the grooves 102 and 104 (step ST6).

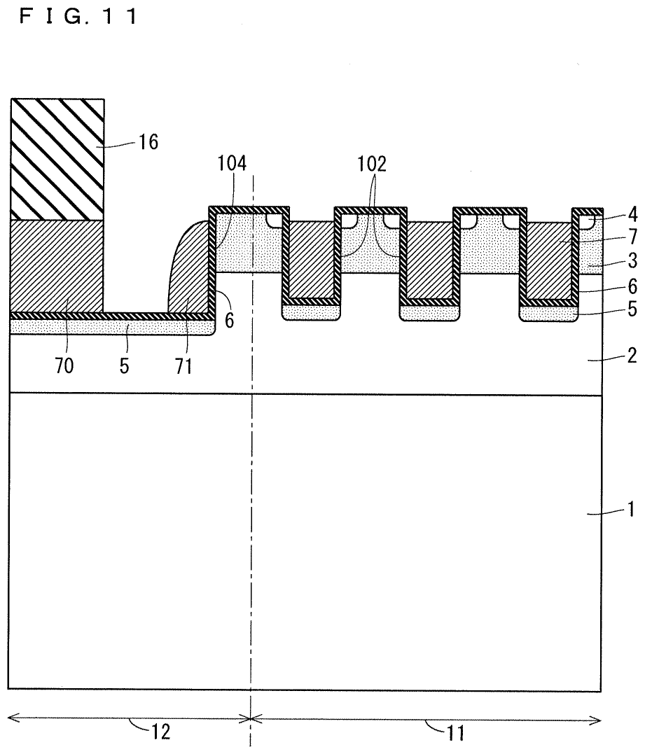

Then, as shown by way of example in FIG. 11, the electrode layer 72 is patterned so as to remove the excess part of the electrode layer 72. Here, highly anisotropic etching such as dry etching using plasma is used for the etching of the electrode layer 72. By performing highly anisotropic etching, the gate electrode 7 is formed inside the grooves 102 that serve as trenches, the gate electrode 70 (a spaced gate electrode formed to be spaced from the inner side surface of the groove 104) is formed immediately under a mask 16 formed in the termination area, and the gate electrode 71 (a contact gate electrode formed in contact with the inner side surface of the groove 104) is formed in a portion of the termination area that is adjacent to the cell area.

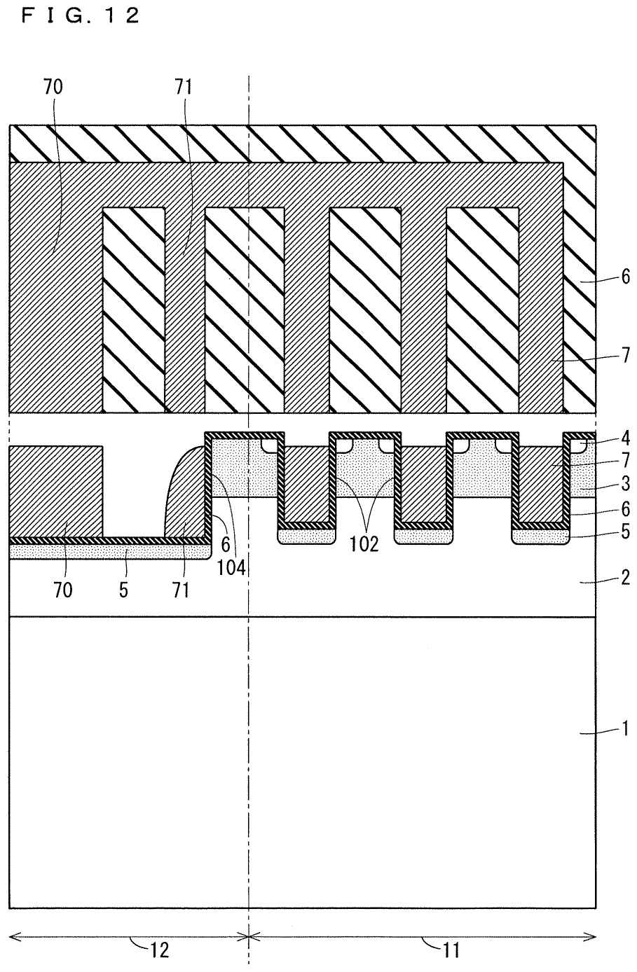

FIG. 12 shows a combination of a schematic plan view and a schematic section view of the structure shown in FIG. 11. As shown by way of example in FIG. 12, the gate electrode 7 formed inside the grooves 102, the gate electrode 70 formed immediately under the mask 16 in the termination area, and the gate electrode 71 formed in the portion of the termination area that is adjacent to the cell area are all connected to one another.

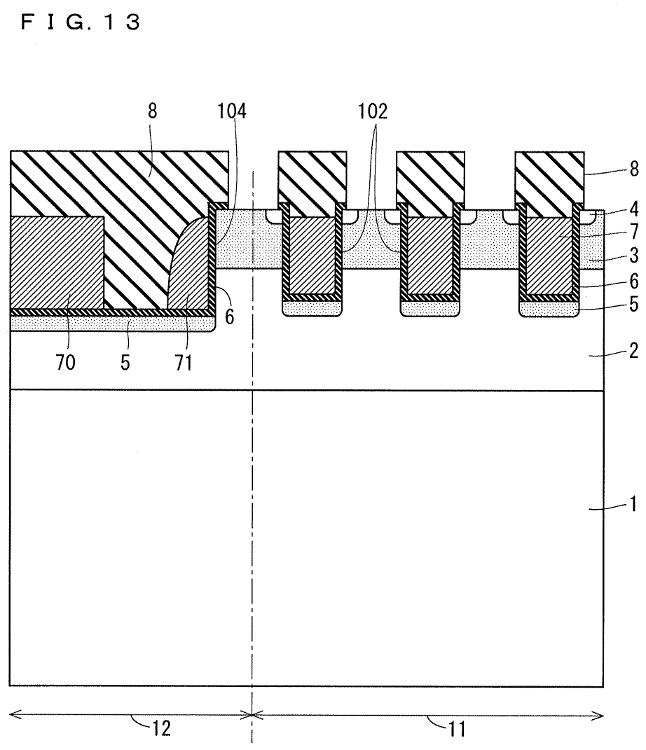

Then, the interlayer insulation film 8 is deposited by chemical vapor deposition (i.e., CVD). Thereafter, as shown by way of example in FIG. 13, the gate insulating film 6 and the excess part of the interlayer insulation film 8 are removed by a photomechanical process and by patterning using an etching process (step ST7).

Regarding the interlayer insulation film 8, the corners of the interlayer insulation film 8 can be rounded by introducing impurities such as boron (B) or phosphorus (P). While the interlayer insulation film 8 is formed by deposition and patterning as described above, it is preferable that the material to be deposited may, for example, be silicon nitride (SiₓN_{y}) or silicon oxide (SiO₂), and the interlayer insulation film 8 may have a thickness of, for example, greater than or equal to 0.5 μm and less than or equal to 2.0 μm.

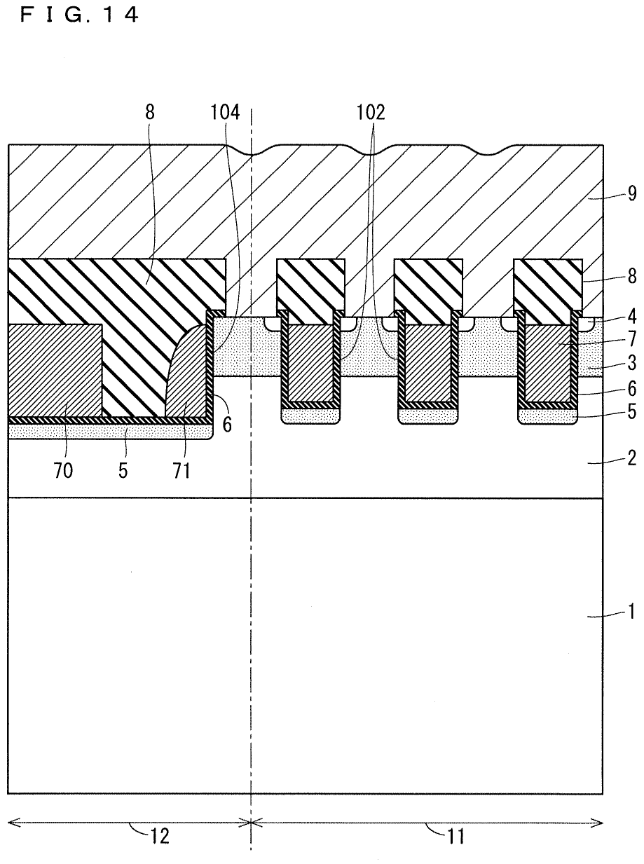

Then, as shown by way of example in FIG. 14, the source electrode 9 is formed by deposition of, for example, aluminum, an aluminum alloy of aluminum and silicon, an aluminum alloy of aluminum and copper, or nickel with an appropriate use of a barrier metal of titanium or a titanium compound such as titanium nitride (TiN).

Thereafter, the n-type SiC substrate 1 of the SiC semiconductor device is thinned as necessary by subjecting a second surface (hereinafter referred to as the “lower surface”) of the n-type SiC substrate 1, which is the surface on the side opposite to the first surface, to mechanical machining using a grinding wheel (step ST9).

Then, the drain electrode 10 is formed by depositing a nickel film having a thickness of approximately 600 nm on the lower surface of the n-type SiC substrate 1 by sputtering or the like as appropriate (step ST10). As a result, the SiC semiconductor device with the structure as shown by way of example in FIG. 1 is formed.

As for the upper surface of the nickel film serving as the drain electrode 10, oxidation of the uppermost surface deteriorates wetting and running properties of solder and nickel, resulting in poor chip bonding. Therefore, a metal with low reactivity to the exterior, such as gold or silver, may be provided as a protective film on the upper surface of the nickel film, and a laminated film formed of, for example, the nickel film and gold or silver may be used as the drain electrode 10.

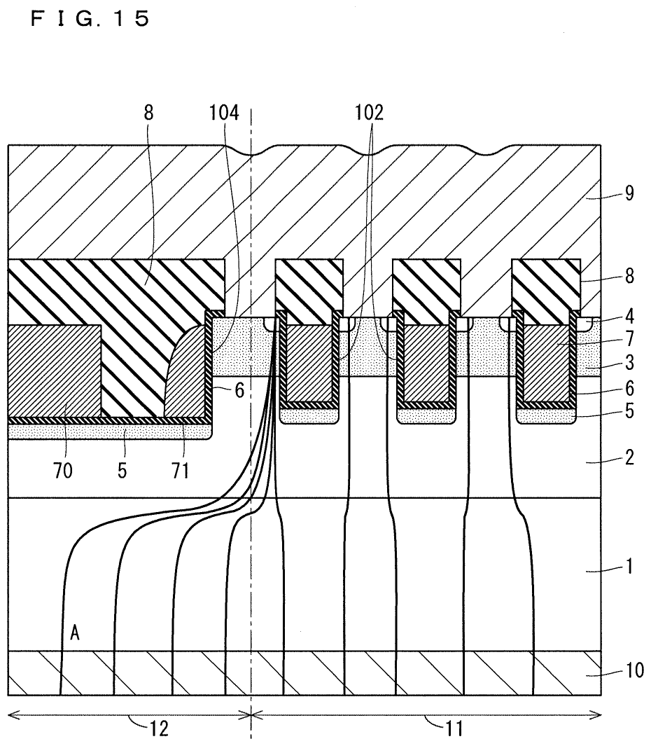

FIG. 15 is a sectional view schematically showing an example of current paths when current flows through the SiC semiconductor device according to the present embodiment.

In FIG. 15, solid lines A indicate current paths when a voltage greater than or equal to a threshold voltage is applied to the gate electrode 7 so that a potential of the source electrode 9 becomes higher than a potential of the drain electrode 10, the threshold voltage being a voltage at which current begins to flow through the SiC semiconductor device.

As shown in FIG. 15, current flowing through the entire surface of the drain electrode 10 is concentrated in the n-type source region 4 on the upper surface side of the SiC semiconductor device. Thus, current flows only in the cell area 11 on the upper surface side of the SiC semiconductor device and does not flow in the termination area 12.

When a difference between the potential of the source electrode 9 and the potential of the drain electrode 10 increases and the electric field in the gate insulating film 6 reaches the breakdown electric field, a breakdown occurs in the gate insulating film 6. If the breakdown point of the gate insulating film 6 is inside the cell area 11, this breakdown point is the point where the current flows, so that the amount of heat generated at the time of breakdown will increase and the gate electrode 7 will melt. On the other hand, if the breakdown point of the gate insulating film 6 is inside the termination area 12, this breakdown point is the point where the current does not flow, so that the amount of heat generated at the time of breakdown will decrease and this will suppress melting of the gate electrode 7.

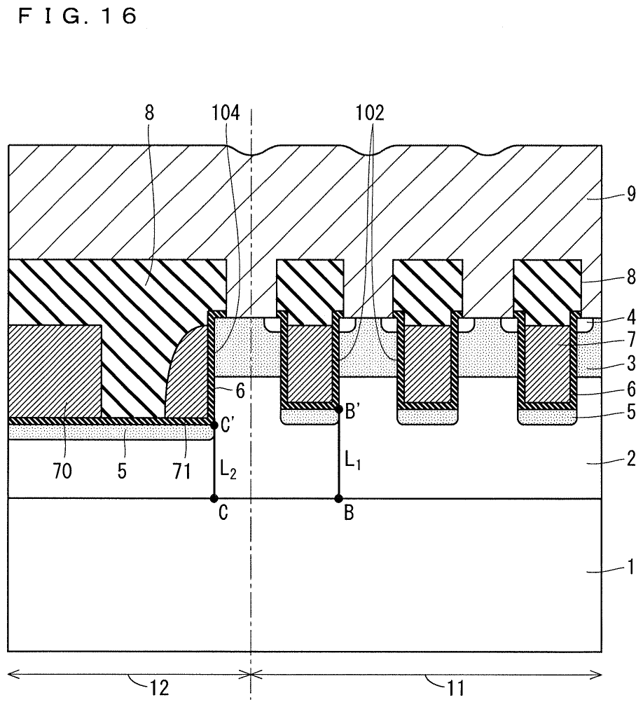

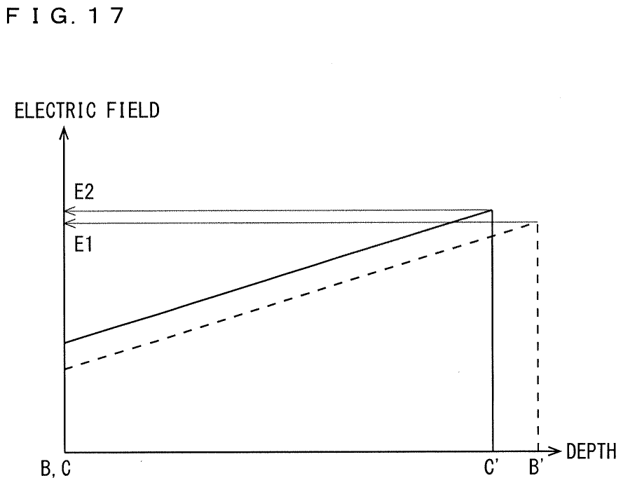

FIG. 16 is a sectional view showing an example of the configuration of the SiC semiconductor device according to the present embodiment. FIG. 17 is a schematic diagram showing the distributions of the electric fields at a section B-B′ and a section C-C′ in FIG. 16. In FIG. 17, the vertical axis represents the electric field, and the horizontal axis represents the depth. In FIG. 17, the distribution of the electric field at the section B-B′ is indicated by the dotted line, and the distribution of the electric field at the section C-C′ is indicated by the solid line.

In FIG. 16, L₁>L₂ is satisfied, where Li is the distance between the bottoms of the grooves 102 and the lower surface of the n-type drift layer 2 in the cell area 11, and L₂ is the distance between the bottom of the groove 104 and the lower surface of the n-type drift layer 2 in the termination area 12. That is, regarding the grooves 102 and 104 formed in the same manner in the upper surface of the p-type base region 3, the groove 104 is formed deeper than the grooves 102.

Then, as shown in FIG. 17, E1<E2 is satisfied, where El is the electric field applied to the bottoms of the grooves 102 in the cell area 11, and E2 is the electric field applied to the bottom of the groove 104 in the termination area 12.

Therefore, the gate insulating film 6 in the termination area 12 reaches the breakdown electric field at a lower voltage than the gate insulating film 6 in the cell area 11 and accordingly, in the SiC semiconductor device according to the present embodiment, a breakdown of the gate insulating film 6 always occurs at a point where no current flows. This reduces the amount of heat generated at the time of breakdown and suppresses melting of the gate electrode 7.

In the case where V1 is the withstand voltage of the SiC semiconductor device, a breakdown of the gate insulating film 6 is supposed not to occur at a voltage lower than V1. Therefore, according to the Gauss's law, the value of L₂ is supposed to satisfy V1<Ec×L₂−(q×N1/εc)×L₂×L₂, where N1 is the impurity concentration in the n-type drift layer 2, Ec is the breakdown electric field of the gate insulating film 6, q is the elementary charge, and ac is the dielectric constant of SiC. This expression is not satisfied if L₂ is too short (too small).

### Second Embodiment

A semiconductor device according to the present embodiment and a method of manufacturing the semiconductor device will be described. In the following description, constituent elements that are identical to those described in the above-described embodiment are illustrated with the same reference signs, and detailed descriptions of these constituent elements shall be omitted as appropriate.

### Configuration of Semiconductor Device

As compared with the first embodiment, the following describes a method of manufacturing a SiC semiconductor device that can satisfy L1>L₂ even in the case where the grooves 102 in the cell area 11 and the groove 104 in the termination area 12 are processed by the same stroke.

Firstly, steps ST1 to ST3 are performed by the manufacturing process similar to that described in the first embodiment. Accordingly, the structure shown in FIG. 5 is formed.

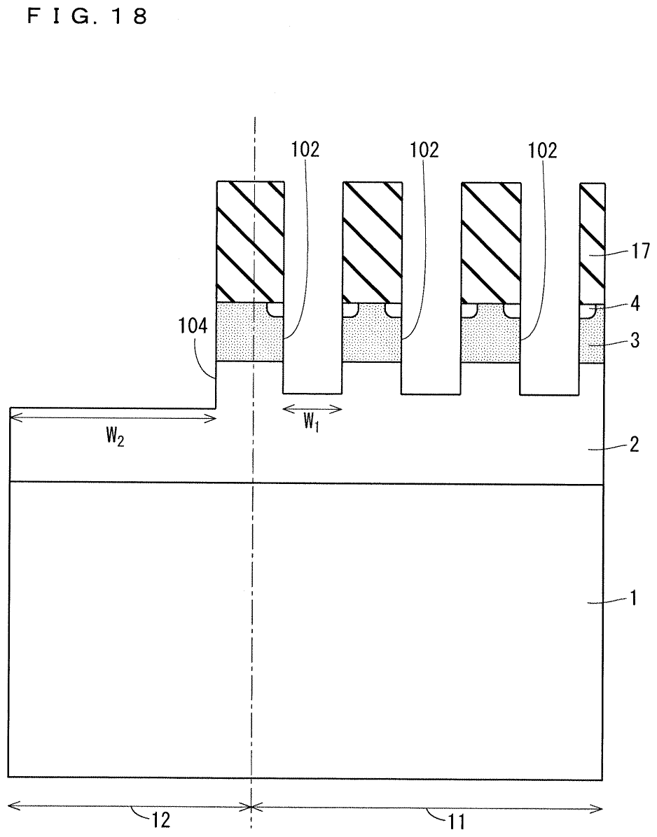

Then, a mask 17 is formed of a resist in the cell area 11 and the termination area 12. Thereafter, as shown by way of example in FIG. 18, the grooves 102 in the cell area 11 and the groove 104 in the termination area 12 are formed by the same stroke by, for example, dry etching using plasma (step ST4). FIG. 18 is a sectional view showing an example of the process of manufacturing the SiC semiconductor device according to the present embodiment.

Here, in order to satisfy L₁>L₂ by performing dry etching by the same stroke, the mask pattern of the mask 17 is formed to satisfy W1<W2, where W1 is the width of the bottoms of the grooves 102 (the width in plan view) in the cell area 11, and W2 is the width of the bottom of the groove 104 (the width in plan view) in the termination area 12.

Since the wider the widths of the bottoms of the grooves, the easier it is for the etching gas to react, if W1<W2 is satisfied, the grooves 102 in the cell area 11 and the groove 104 in the termination area 12 that satisfy L₁>L₂ can be formed by one operation by performing dry etching by the same stroke.

As in the first embodiment, if it is not possible to provide a mask capable of forming the grooves 102 in the cell area 11 or a mask capable of forming the groove 104 in the termination area 12, deeper grooves may be formed by depositing, for example, an oxide film made from TEOS on the upper surface of the p-type base region 3 shown in FIG. 5 and dry-etching this oxide film by using a resist mask.

According to the manufacturing method described above, the structure shown in FIG. 7 of the first embodiment is formed. Thereafter, as shown by way of example in FIG. 8, the p-type base region 5 may be formed on the bottoms of the grooves 102 and 104 in order to alleviate the electrical fields applied to the bottoms of the trench gates. Examples of the p-type impurity include boron (B) and aluminum (Al).

Then, the SiC semiconductor device with the structure as shown by way of example in FIG. 1 is formed through the process similar to steps ST5 to ST10 described in the first embodiment.

According to the manufacturing method described above, some steps including the step of forming a resist mask for forming the groove 104 in the termination area 12, the step of performing dry etching, and the step of cleaning the resist may be omitted as compared with the first embodiment. Therefore, the SiC semiconductor device can be manufactured at a lower manufacturing cost.

Here, in the case where the grooves 102 in the cell area 11 and the groove 104 in the termination area 12 are formed by the same stroke by the manufacturing method according to the present embodiment, it is difficult to control both of the lengths L₁ and L₂ as compared with the case where these grooves are formed separately as described in the first embodiment. Therefore, in order for the shorter length L₂ to satisfy L₂=V1<Ec×L₂−(q×N1/Ωc)×L₂×L₂, it is necessary to achieve the desired value of V1 by controlling process conditions such as gas type, pressure, or temperature during dry etching.

If L₂=V1<Ec×L₂−(q×N1/Ωc)×L₂×L₂ and W1<W2 are both satisfied, it is possible to achieve the desired value of V1 and manufacture the SiC semiconductor device that satisfies L₁>L₂.

### Third Embodiment

A semiconductor device according to the present embodiment and a method of manufacturing the semiconductor device will be described. In the following description, constituent elements that are identical to those described in the above-described embodiments are illustrated with the same reference signs, and detailed descriptions of these constituent elements shall be omitted as appropriate.

### Configuration of Semiconductor Device

As compared with the first embodiment, the following describes a SiC semiconductor device that satisfies 90°<α, where a is the angle of the corners between the bottom and side surfaces of a groove 104A in the termination area 12 and that further satisfies 90°<α>90°+β as a condition for forming the groove 104A that is spaced from the outermost groove 102 in the cell region 11 when β=arctan (B/A), where A is the depth of the groove 104A in the termination area 12 that surrounds the cell area 11 in plan view, and B is the distance between the outermost groove 102 in the cell area 11 and the groove 104A in the termination area 12.

Firstly, steps ST1 to ST3 are performed by a manufacturing process similar to that described in the first embodiment. Accordingly, the structure shown in FIG. 5 is formed.

Then, as shown by way of example in FIG. 6, after the mask 14 for the cell areas is formed of a resist, the trench-type grooves 102 are formed in the cell area by, for example, dry etching using plasma (step ST4).

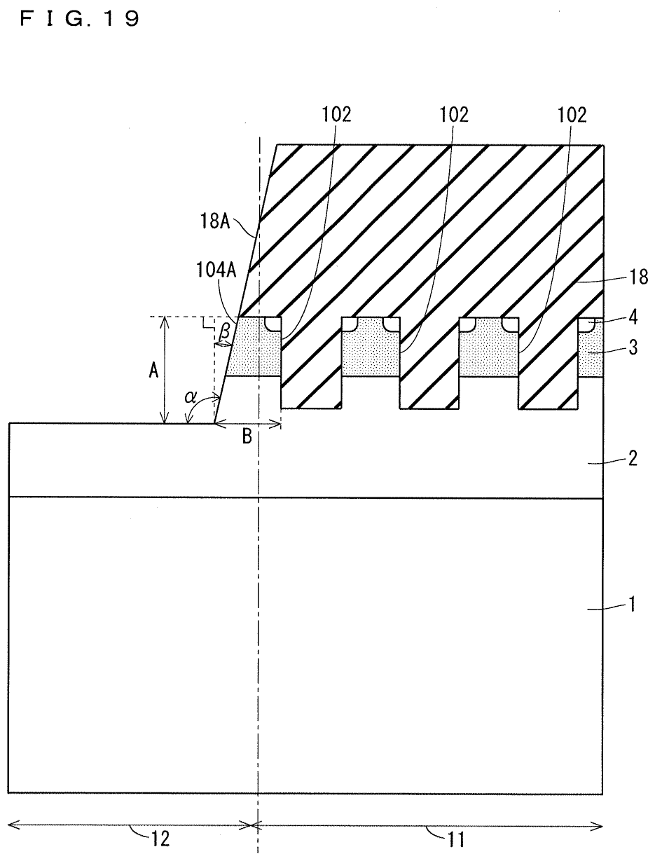

Then, a mask 18 is formed of a resist in the cell area 11 and the termination area 12. The mask 18 has an inclined surface 18A at a position corresponding to the boundary between the termination area 12 and the cell area 11. Thereafter, as shown by way of example in FIG. 19, the groove 104A in the termination area 12 is formed by, for example, dry etching using plasma. FIG. 19 is a sectional view showing an example of the process of manufacturing the SiC semiconductor device according to the embodiment.

The groove 104A has an inclined side surface that corresponds to the inclined surface 18A. Specifically, the groove 104A is formed to satisfy 90°<α<90°+β, where a is the angle between the bottom and side surfaces of the groove 104A in the termination area 12.

As in the first embodiment, if it is not possible to provide a mask capable of forming the grooves 102 in the cell area 11 or a mask capable of forming the groove 104A in the termination area 12, deeper grooves may be formed by depositing, for example, an oxide film made from TEOS on the upper surface of the p-type base region 3 shown in FIG. 5 and dry-etching this oxide film by using a resist mask.

In the case of forming a mask for the aforementioned oxide film, the mask 18 with an inclination may also be used to provide the mask for the oxide film with an inclination. Thereafter, the p-type base region 5 may be formed on the bottoms of the grooves 102 and 104 in order to alleviate electric fields applied to the bottoms of the trench gates. Examples of the p-type impurity include boron (B) and aluminum (Al).

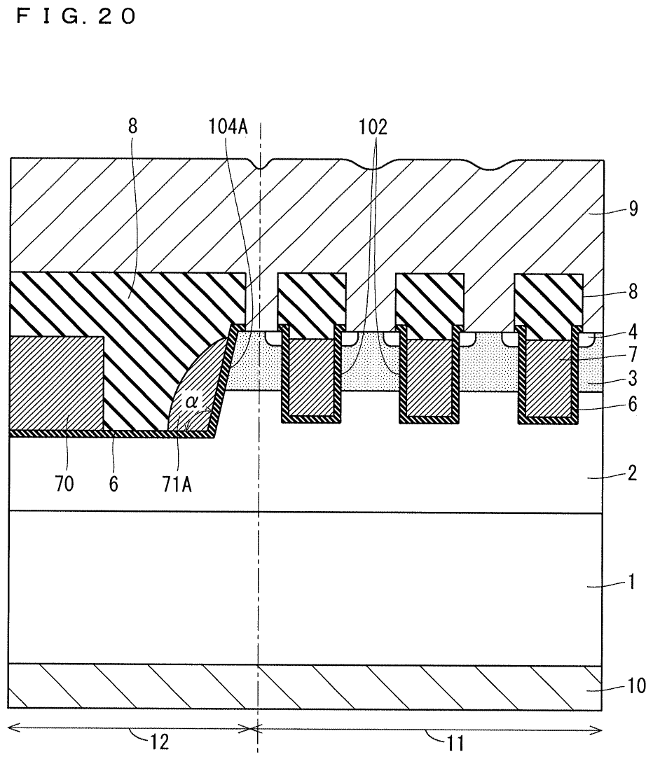

Then, through the process similar to steps ST5 to ST10 described in the first embodiment, the SiC semiconductor device that satisfies 90°<α>90°+β is formed as shown by way of example in FIG. 20. FIG. 20 is a sectional view showing an example of a configuration of the SiC semiconductor device according to the present embodiment.

In the SiC semiconductor device according to the present embodiment, the angle a between the bottom and side surfaces of the groove 104A in the termination area 12 is greater than 90° as compared with the first embodiment. Therefore, it is possible to alleviate the electric fields concentrated at the inner corners of the groove 104A.

The electric field applied to the corners of a gate electrode 71A that is in contact with the side surface of the groove 104A in the termination area 12 can be approximately considered as the electric field produced by a circular electrode.

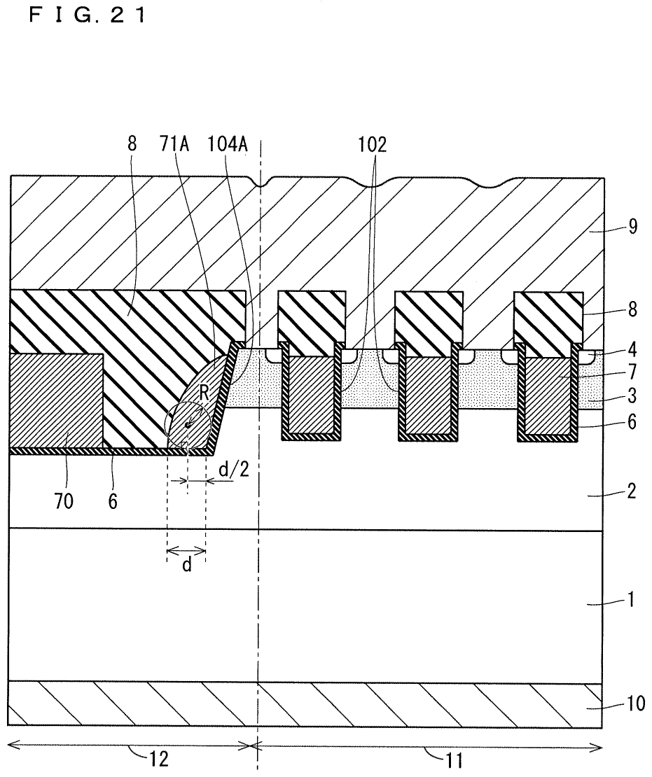

FIG. 21 is a sectional view showing an example of the configuration of the SiC semiconductor device according to the present embodiment. As shown by way of example in FIG. 21, considering a circular electrode with a radius R that is in contact with the bottom and side wall of the groove 104A and that passes through the perpendicular bisector of the bottom of the gate electrode 71A formed in contact with the side surface of the groove 104A in the termination area 12, the magnitude of the electric field is expressed by E [symbol] V2/R according to the Gauss's law, so that the electric field becomes smaller as R increases, where V2 is the potential difference between the source electrode 9 and the drain electrode 10. Besides, since the relationship of R/(d/2)=tan(α/2) holds true for α and R, the electric field becomes smaller as a increases.

As a result, the electric field applied to the gate insulating film 6 becomes smaller as α increases, which reduces the occurrence of a breakdown in the gate insulating film 6.

### Fourth Embodiment

A semiconductor device according to the present embodiment and a method of manufacturing the semiconductor device will be described. In the following description, constituent elements that are identical to those described in the above-described embodiments are illustrated with the same reference signs, and detailed descriptions of these constituent elements shall be omitted as appropriate.

### Configuration of Semiconductor Device

As compared with the first embodiment, the following describes a SiC semiconductor device that can control the distance between the side surface of the groove 104 and the gate electrode 70 formed inside the groove 104 in the termination area 12 that surrounds the cell area 11 in plan view.

Firstly, steps ST1 to ST6 are performed by the manufacturing process similar to that described in the first embodiment. Accordingly, the structure shown in FIG. 11 is formed.

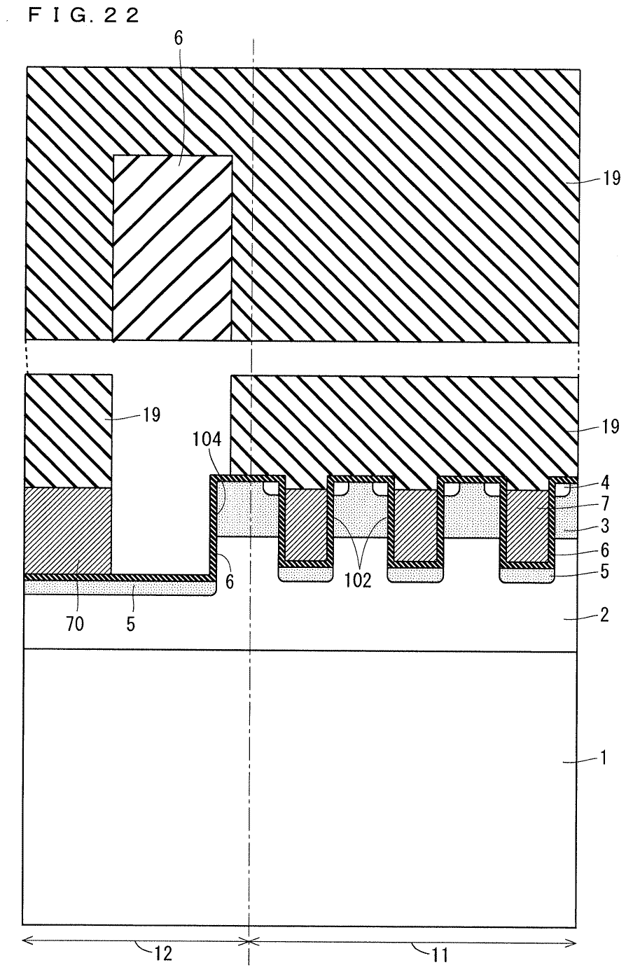

Then, in order to remove a portion of the gate electrode 71 that is in contact with the side surface of the groove 104, as shown by way of example in FIG. 22, patterning using a mask 19 formed of a resist and subsequent wet etching or dry etching are performed to remove the portion of the gate electrode 71 that is in contact with the side surface of the groove 104. Alternatively, a portion of the gate electrode 71 that is in contact with the side surface of the groove 104 may be removed by dry etching using the mask 19 formed of a resist and subsequent wet etching or dry etching (i.e., by multiple etching processes). In this way, the gate electrode 70 is formed to be spaced from the inner side surface of the groove 104. FIG. 22 is a diagram that is a combination of a plan view and a section view showing an example of the process of manufacturing the SiC semiconductor device according to the present embodiment.

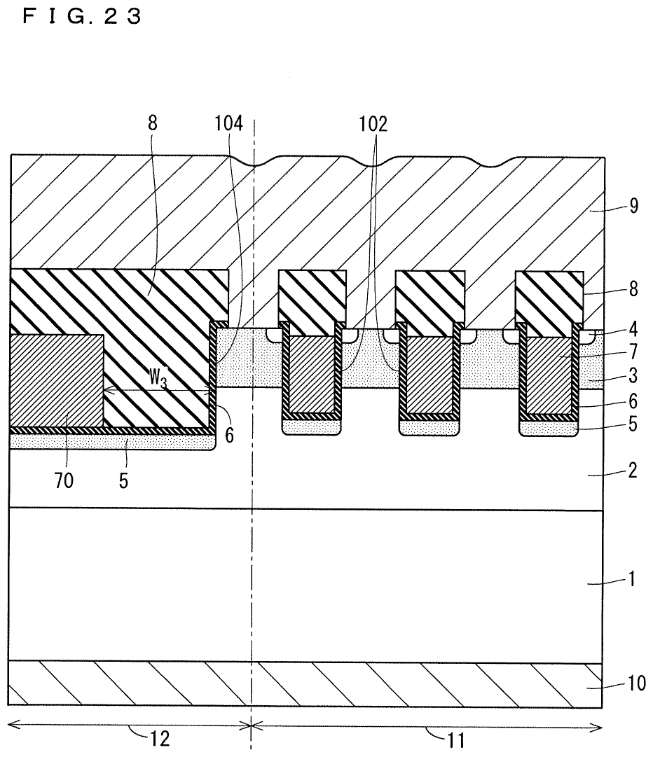

Then, through the process similar to steps ST7 to ST10 described in the first embodiment, the SiC semiconductor device with the structure shown by way of example in FIG. 23 is formed. FIG. 23 is a sectional view showing an example of a configuration of the SiC semiconductor device according to the present embodiment.

According to the manufacturing method of the present embodiment, the magnitude of W3 that is the distance between the gate electrode 70 and the side surface of the groove 104 can be set by adjusting a mask pattern in the process of forming the gate electrode 70 in the termination area 12 shown in FIG. 11.

By increasing W3, it is possible to increase the distance between the cell area 11 where the current flows (see FIG. 15) and the point of electric field concentration in the groove 104 in the termination area 12. This suppresses melting of the gate electrode 7 as compared with the case described in the first embodiment.

On the other hand, increasing W3 also increases the surface area of the SiC semiconductor device and consequently increases the manufacturing cost of the SiC semiconductor device.

According to the manufacturing method of the present embodiment, since W3 can be controlled to an arbitrary length, it is possible to adjust W3 to an optimum value by comparing the manufacturing cost and resistance to melting.

Note that the inner side surface of the groove 104 where only the gate electrode 70 shown in FIGS. 22 and 23 is formed may be an inclined surface as shown in FIGS. 19, 20, and 21.

### Fifth Embodiment

A semiconductor device according to the present embodiment and a method of manufacturing the semiconductor device will be described. In the following description, constituent elements that are identical to those described in the above-described embodiments are illustrated with the same reference signs, and detailed descriptions of these constituent elements shall be omitted as appropriate.

### Configuration of Semiconductor Device

As compared with the first embodiment, the following describes a SiC semiconductor device that can suppress heat generation in the termination area 12 where electric fields are concentrated, by lowering the current density of the current flowing in the source electrode located adjacent to the termination area 12.

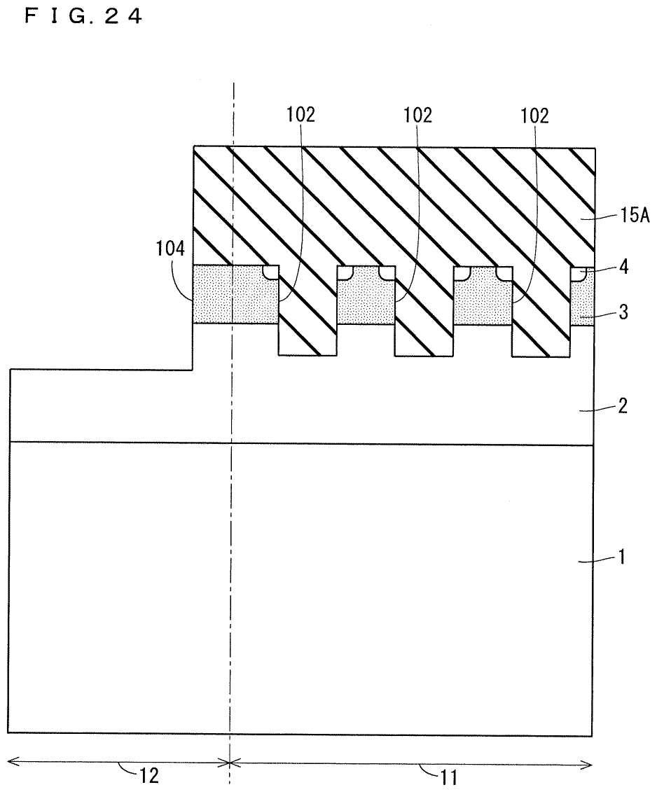

Firstly, steps ST1 to ST3 are performed by a manufacturing process similar to that described in the first embodiment. Thereafter, in step ST4, after a mask 15A different from the mask 14 is formed of a resist for the termination area, the trench-type groove 104 in the termination area is formed in the upper surface of the p-type base region 3 by, for example, dry etching using plasma (see FIG. 24). Here, the distance between the groove 102 and the groove 104 formed using the mask 15A is greater than the distance between the grooves 102. The groove 104 in the termination area 12 is formed deeper than the grooves 102. FIG. 24 is a sectional view showing an example of the process of manufacturing the SiC semiconductor device according to the embodiment.

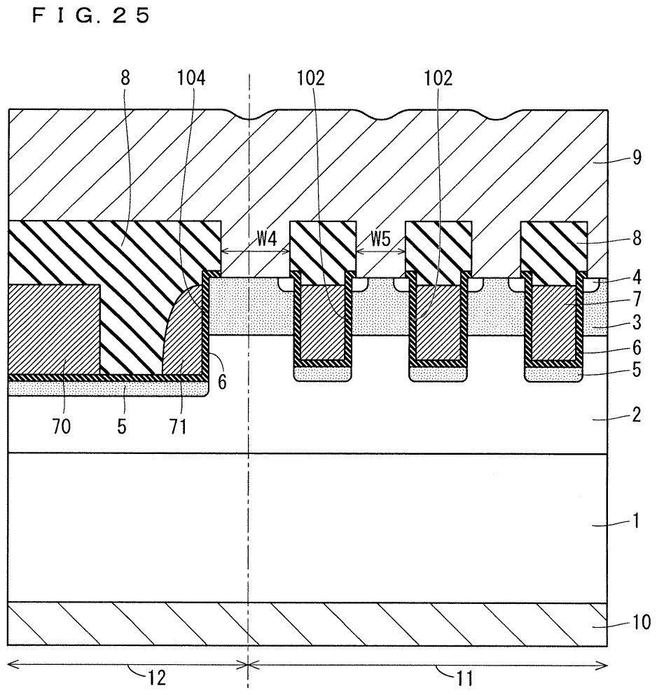

Then, through the process similar to steps ST5 to ST10 described in the first embodiment, the SiC semiconductor device with the structure shown by way of example in FIG. 25 is formed. FIG. 25 is a sectional view showing an example of a configuration of the SiC semiconductor device according to the present embodiment.

As shown in FIG. 25, the distance (W4) between the interlayer insulation film 8 formed on the groove 104 and the interlayer insulation film 8 formed on the groove 102 is greater than the distance (W5) between the interlayer insulation films 8 formed on the grooves 102. By increasing W4, it is possible to lower the current density in the source electrode 9 between the termination area 12 and the cell area 11 where the current flows. This reduces heat generation caused by the current flowing in the termination area 12 and suppresses melting.

On the other hand, increasing W4 also increases the surface area of the SiC semiconductor device and consequently increases the manufacturing cost of the SiC semiconductor device.

According to the manufacturing method of the present embodiment, since W4 can be controlled to an arbitrary length depending on the shape of the mask 15A, W4 can be controlled to an optimum value by comparing the manufacturing cost and resistance to melting.

Note that the inner side surface of the groove 104 shown in FIGS. 24 and 25 may be an inclined surface as shown in FIGS. 19, 20, and 21.

### Sixth Embodiment

A semiconductor device according to the present embodiment and a method of manufacturing the semiconductor device will be described. In the following description, constituent elements that are identical to those described in the above-described embodiments are illustrated with the same reference signs, and detailed descriptions of these constituent elements shall be omitted as appropriate.

### Configuration of Semiconductor Device

As compared with the first embodiment, the following describes a SiC semiconductor device that can suppress heat generation in the termination area 12 where electric fields are concentrated, by interrupting the current flowing into the side wall of the groove 104 in the termination area 12.

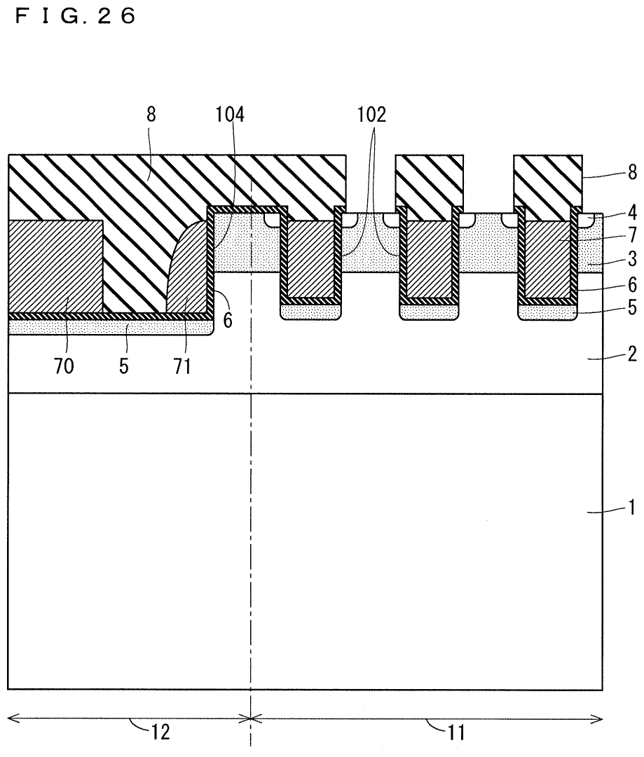

Firstly, steps ST1 to ST6 are performed by a manufacturing process similar to that described in the first embodiment. Thereafter, in step ST7, the interlayer insulation film 8 in the termination area 12 and the interlayer insulation film 8 in the cell area 11, which are adjacent to each other, are connected to each other by changing a photomechanical process for forming the interlayer insulation film 8 and patterning using an etching process. By so doing, the structure shown in FIG. 26 is formed. FIG. 26 is a sectional view showing an example of the process of manufacturing the SiC semiconductor device according to the embodiment.

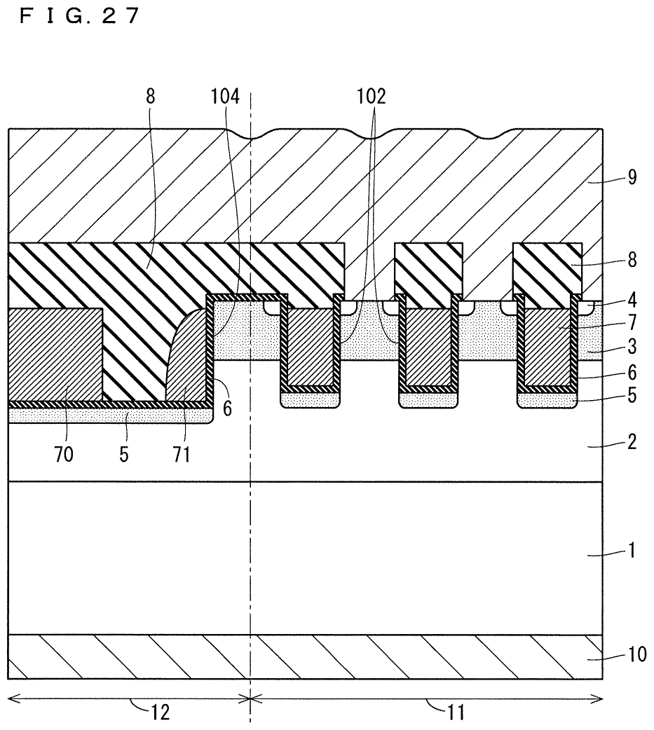

Then, through the process similar to steps ST8 to ST10 described in the first embodiment, the SiC semiconductor device with a structure shown by way of example in FIG. 27 is formed. FIG. 27 is a sectional view showing an example of a configuration of the SiC semiconductor device according to the present embodiment.

In the structure shown in FIG. 27, the source electrode 9 adjacent to the termination area 12 is blocked without contact with the p-type base region 3. This structure can interrupt the current flowing between the cell area 11 and the termination area 12. Therefore, it is possible to suppress heat generation caused by the current flowing in the termination area 12 and suppress melting.

Note that the inner side surface of the groove 104 shown in FIGS. 26 and 27 may be an inclined surface as shown in FIGS. 19, 20, and 21.

### Seventh Embodiment

A power converter according to the present embodiment and a method of manufacturing the power converter will be described. In the following description, constituent elements that are identical to those described in the above-described embodiments are illustrated with the same reference signs, and detailed descriptions of these constituent elements shall be omitted as appropriate.

### Configuration of Power Converter

The present embodiment describes that the semiconductor device according to the embodiments described above is applied to a power converter. The power converter to which the semiconductor device is applied is not limited to a specific application, but the following describes a case in which the semiconductor device is applied to a three-phase inverter.

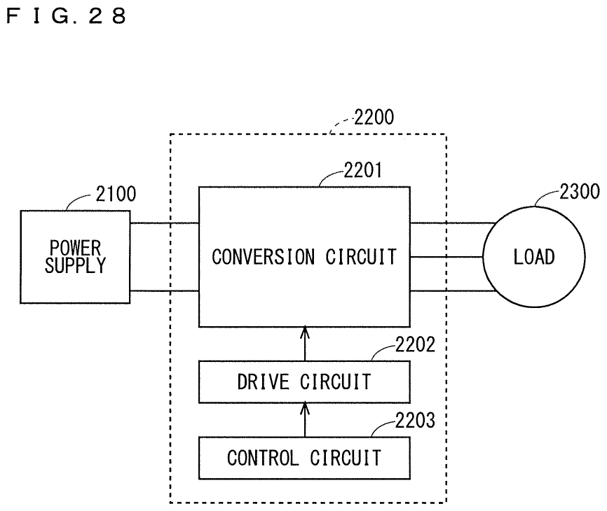

FIG. 28 is a diagram conceptually showing an example of a configuration of a power conversion system that includes the power converter according to the present embodiment.

As shown by way of example in FIG. 28, the power conversion system includes a power supply 2100, a power converter 2200, and a load 2300. The power supply 2100 is a direct-current (DC) power supply and supplies DC power to the power converter 2200. The power supply 2100 may be configured as a variety of power supplies and may be configured as, for example, a DC system, a solar cell, or a storage battery. The power supply 2100 may also be configured as a rectifier circuit or an AC-DC converter that is connected to an alternating-current (AC) system. The power supply 2100 may also be configured as a DC-DC converter that converts DC power output from a DC system into predetermined electric power.

The power converter 2200 is a three-phase inverter connected between the power supply 2100 and the load 2300. The power converter 2200 converts DC power supplied from the power supply 2100 into AC power and further supplies the AC power to the load 2300.

As shown by way of example in FIG. 28, the power converter 2200 includes a conversion circuit 2201 that converts DC power into AC power and outputs converted power, a drive circuit 2202 that outputs drive signals for driving switching elements of the conversion circuit 2201, and a control circuit 2203 that outputs a control signal for controlling the drive circuit 2202 to the drive circuit 2202.

The load 2300 is a three-phase electric motor that is driven by the AC power supplied from the power converter 2200. Note that the load 2300 is not limited to a specific application and serves as an electric motor mounted on a variety of electrical apparatuses, and for example, the load 2300 may be used as an electric motor for use in hybrid automobiles, electric vehicles, railway vehicles, elevators, or air conditioners.

The following describes details of the power converter 2200. The conversion circuit 2201 includes switching elements and freewheeling diodes (not shown here). When the switching elements perform a switching operation, DC power supplied from the power supply 2100 is converted into AC power and supplied to the load 2300.

There are various specific circuit configurations for the conversion circuit 2201. The conversion circuit 2201 according to the present embodiment is a two-level three-phase full-bridge circuit and includes six switching elements and six freewheeling diodes that are connected in inverse parallel with the six switching elements, respectively.

The semiconductor device according to any one of the embodiments described above is applied to at least either the switching elements or the freewheeling diodes of the conversion circuit 2201. Each two of the six switching elements are connected in series and configure upper and lower arms, and each pair of upper and lower arms configures each phase of the full-bridge circuit (i.e., a U phase, a V phase, and a W phase). Then, the output terminal of each pair of upper and lower arms (i.e., three output terminals of the conversion circuit 2201) is connected to the load 2300.

The drive circuit 2202 generates drive signals for driving the switching elements of the conversion circuit 2201 and further supplies the drive signals to control electrodes of the switching elements of the conversion circuit 2201. Specifically, a drive signal for turning on a switching element and a drive signal for turning off a switching element are output to the control electrodes of the switching elements in accordance with the control signal that is output from the control circuit 2203 described later.

When a switching element is kept in the on state, the drive signal is a voltage signal (i.e., an ON signal) of greater than or equal to the threshold voltage of the switching element, and when a switching element is kept in the off state, the drive signal is a voltage signal of less than or equal to the threshold value of the switching element (i.e., an OFF signal).

The control circuit 2203 controls the switching elements of the conversion circuit 2201 such that desired electric power is supplied to the load 2300. Specifically, the duration of time each switching element of the conversion circuit 2201 is supposed to be in the on state (i.e., the ON time) is calculated based on the electric power to be supplied to the load 2300. For example, the conversion circuit 2201 may be controlled by PWM control in which the ON time of each switching element is modulated in response to a voltage to be output.

Then, the control circuit 2203 outputs a control command (i.e., a control signal) to the drive circuit 2202 so that, at each point in time, the ON signal is output to a switching element that is supposed to be turned on, and the OFF signal is output to a switching element that is to be turned off. In accordance with this control signal, the drive circuit 2202 outputs the ON or OFF signal as the drive signal to the control electrode of each switching element.

Since the power converter 2200 according to the present embodiment applies the semiconductor device according to any one of the embodiments described above to each switching element of the conversion circuit 2201, it is possible to stabilize on-state resistance after a current-carrying cycle.

While the present embodiment describes an example in which the semiconductor device according to any one of the embodiments described above is applied to the two-level three-phase inverter, examples of the application are not limited to this example, and the semiconductor device according to any one of the embodiments described above may be applied to a variety of power converters.

While the present embodiment describes the two-level power converter, the semiconductor device according to any one of the embodiments described above may be applied to any other power converter such as a three-level or multi-level power converter. In the case where electric power is supplied to a single-phase load, the semiconductor device according to any one of the embodiments described above may be applied to a single-phase inverter.

In the case where electric power is supplied to a DC load or the like, the semiconductor device according to any one of the embodiments described above may be applied to a DC-DC converter or an AC-DC converter.

The use of the power converter that applies the semiconductor device according to any one of the embodiments described above is not limited to the case where the aforementioned load is an electric motor, and for example, the power converter may also be applied as a power supply device for use in electric spark machines, laser beam machines, dielectric heat cooking appliances, or non-contact feed systems. The power converter that applies the semiconductor device according to any one of the embodiments described above may also be used as a power conditioner for use in systems such as a photovoltaic power generating system or a power storage system.

The semiconductor switching elements used in the embodiments described above are not limited to the switching elements formed of a silicon (Si) semiconductor, and for example, the semiconductor switching elements may be formed of a non-Si semiconductor material that has a wider bandgap than the Si semiconductor.

Examples of wide-bandgap semiconductors serving as non-Si semiconductor materials include silicon carbide, gallium nitride-based materials, and diamond.

The switching elements formed of a wide-bandgap semiconductor are also applicable in a high-voltage area where unipolar operations are difficult for the Si semiconductors, and it is possible to significantly reduce switching losses that occur during switching operations. This allows a significant reduction in power loss.

The switching elements formed of a wide-bandgap semiconductor have low power loss and high heat resistance. Thus, in the case of configuring a power module with a cooler, it is possible to reduce the size of a cooling fin of a heat sink. This allows further downsizing of a semiconductor module.

The switching elements formed of a wide-bandgap semiconductor are suitable for high-frequency switching operations. Thus, when the switching elements are applied to a converter circuit with high demand for higher frequencies, devices such as a reactor or a capacitor that are connected to the converter circuit can be made smaller by increasing the frequencies of the switching elements.

Therefore, the semiconductor switching elements according to the embodiments described above can achieve similar effects even when serving as switching elements formed of a wide-bandgap semiconductor such as silicon carbide.

### Advantageous Effects of Above-Described Embodiments

Next, examples of advantageous effects achieved by the above-described embodiments will be described. In the following description, the advantageous effects will be described based on specific configurations shown as examples in the multiple embodiments described above, but may be replaced with other specific configurations shown as examples in the specification of the present application to the extent that similar advantageous effects are achieved. That is, although only one of the corresponding specific configurations may be described below as a representative example for the sake of convenience, the specific configuration described as a representative may be replaced with any other corresponding specific configuration.

This replacement may be made across multiple embodiments. In other words, the configurations shown as examples in different embodiments may be combined to produce the same effect.

According to the embodiments described above, the semiconductor device includes the n-type SiC substrate 1, the n-type drift layer 2, the p-type base region 3, at least one first groove, the second groove, the n-type source region 4, the first gate electrode, at least one second gate electrode, the interlayer insulation film 8, the source electrode 9, and the drain electrode 10. Here, the first groove corresponds to, for example, the grooves 102. The second groove corresponds to, for example, the groove 104 or 104A. The first gate electrode corresponds to, for example, the gate electrode 7. The second gate electrode corresponds to, for example, the gate electrode 70, 71, or 71A. The n-type drift layer 2 is formed on the upper surface of the n-type SiC substrate 1. The p-type base region 3 is formed in the surface layer of the n-type drift layer 2. The grooves 102 are formed from the upper surface of the p-type base region 3 to the interior of the n-type drift layer 2 in the cell area 11. The groove 104 is formed from the upper surface of the p-type base region 3 to the interior of the n-type drift layer 2 in the termination area 12 that surrounds the cell area 11 in plan view. The n-type source region 4 is formed partially in the surface layer of the p-type base region 3 to sandwich the grooves 102. The gate electrode 7 is formed inside the grooves 102 and surrounded by the gate insulating film 6. The gate electrode 70 is formed inside the groove 104 and surrounded by the gate insulating film 6. The interlayer insulation film 8 is formed to cover the gate electrodes 7 and 70. The source electrode 9 is formed in contact with the n-type source region 4. The drain electrode 10 is formed on the lower surface of the n-type SiC substrate 1 that is the surface on the side opposite to the upper surface of the n-type SiC substrate. Here, the gate electrodes 7 and 70 are electrically connected to each other. The groove 104 is deeper than the grooves 102.

In this configuration, when a high voltage is applied, the electric field at the bottom of the groove 104 in the termination area 12 becomes greater than the electric field at the bottoms of the grooves 102 in the cell area 11. As a result, a breakdown of the gate insulating film 6 is more likely to occur in the termination area 12 and is relatively less likely to occur in the cell area 11 where a large current flows. This suppresses heat generation at the breakdown point, and as a result, suppresses melting of the gate electrode 7.

Note that similar advantageous effects can also be achieved even if other configurations, examples of which are shown in the specification of the present application, are added as appropriate to the above-described configuration, i.e., even if other configurations described in the specification of the present application that were not recited as the above-described configuration are added as appropriate.

According to the embodiments described above, the width (W1) of the grooves 102 in plan view is narrower than the width (W2) of the groove 104 in plan view. In this configuration, the wider the width of the bottoms of the trenches, the easier it is for an etching gas to react. Thus, if W1<W2 is satisfied, it is possible to form the grooves 102 in the cell area 11 and the groove 104 in the termination area 12 that satisfy L₁>L₂ by one operation, instead of by separate operations, by performing dry etching by the same stroke.

According to the embodiments described above, 90% a is satisfied, where a is the angle of the corners between the bottom and side surfaces of the groove 104A in the termination area 12. With this configuration, it is possible to alleviate the concentration of the electric field at the inner corners of the groove 104. This reduces the occurrence of a breakdown in the gate insulating film 6.

According to the embodiments described above, the gate electrode 70 is formed to be spaced from the inner side surface of the groove 104. With this configuration, W3 can be adjusted to an optimum value by comparing the manufacturing cost of the SiC semiconductor device and resistance to melting.

According to the embodiments described above, the second gate electrode includes the spaced gate electrode (the gate electrode 70) formed to be spaced from the inner side surface of the groove 104, and the contact gate electrode (the gate electrodes 71 and 71A) formed in contact with the inner side surface of the groove 104. With this configuration, when a high voltage is applied, the electric field at the bottom of the groove 104 in the termination area 12 becomes greater than the electric field at the bottoms of the grooves 102 in the cell area 11. Therefore, a breakdown of the gate insulating film 6 is more likely to occur in the termination area 12 and is relatively less likely to occur in the cell area 11 where a large current flows.

According to the embodiments described above, the power converter includes the semiconductor device described above and further includes the conversion circuit 2201 that converts input electric power and outputs converted electric power, the drive circuit 2202 that outputs drive signals for driving the semiconductor device to the semiconductor device, and the control circuit 2203 that outputs a control signal for controlling the drive circuit 2202 to the drive circuit 2202. With this configuration, when a high voltage is applied, the electric field at the bottom of the groove 104 in the termination area 12 becomes greater than the electric field at the bottoms of the grooves 102 in the cell area 11. Therefore, a breakdown of the gate insulating film 6 is more likely to occur in the termination area 12 and is relatively less likely to occur in the cell area 11 where a large current flows. This suppresses heat generation at a breakdown point, and as a result, suppresses melting of the gate electrode 7.

According to the embodiments described above, in the method of manufacturing the semiconductor device, the n-type drift layer 2 is formed on the upper surface of the n-type SiC substrate 1 of the first conductivity type. Then, the p-type base region 3 of the second conductivity type different from the first conductivity type is formed in the surface layer of the n-type drift layer 2. Then, the n-type source region 4 of the first conductivity type is formed partially in the surface layer of the p-type base region 3. Then, at least one groove 102 is formed from the upper surface of the n-type source region 4 to the interior of the n-type drift layer 2 in the cell area 11. Then, the groove 104 is formed from the upper surface of the n-type source region 4 to the interior of the n-type drift layer 2 in the termination area 12 that surrounds the cell area 11 in plan view. Then, the gate electrode 7 is formed inside the groove 102 and surrounded by the gate insulating film 6. Then, at least one gate electrode 70 is formed inside the groove 104 and surrounded by the gate insulating film 6. Then, the interlayer insulation film 8 is formed to cover the gate electrode 7 and the gate electrode 70. Then, the source electrode 9 is formed in contact with the n-type source region 4. Then, the drain electrode 10 is formed on the lower surface of the n-type SiC substrate 1 that is the surface on the side opposite to the upper surface of the n-type SiC substrate. Here, the gate electrodes 7 and 70 are electrically connected to each other. The groove 104 is deeper than the groove 102.

With this configuration, when a high voltage is applied, the electric field at the bottom of the groove 104 in the termination area 12 becomes greater than the electric field at the bottom of the groove 102 in the cell area 11. Therefore, a breakdown of the gate insulating film 6 is more likely to occur in the termination area 12 and is relatively less likely to occur in the cell area 11 where a large current flows. This suppresses heat generation at a breakdown point, and as a result, suppresses melting of the gate electrode 7.

Unless otherwise specified, the order in which the processes are performed may be changed.

Note that similar advantageous effects can also be achieved even if other configurations, examples of which are shown in the specification of the present application, are added as appropriate to the above-described configuration, i.e., even if other configurations described in the specification of the present application that were not recited as the above-described configuration are added as appropriate.

According to the embodiments described above, forming the grooves 102 corresponds to forming the grooves 102 by using the first mask (e.g., the mask 14). Forming the groove 104 corresponds to forming the groove 104 by using the second mask (e.g., the mask 15) different from the mask 14. With this configuration, the groove 104 in the termination area 12 is formed deeper than the grooves 102 in the cell area 11.

According to the embodiments described above, forming the second gate electrode corresponds to forming the gate electrode 70 to be spaced from the inner side surface of the groove 104 by etching the interior of the groove 104. With this configuration, W3 can be controlled to an arbitrary length and therefore can be controlled to an optimum value by comparing the manufacturing cost of the SiC semiconductor device and resistance to melting.

According to the embodiments described above, forming the second gate electrode corresponds to forming the gate electrode 70 to be spaced from the inner side surface of the groove 104 by dry-etching the interior of the groove 104 and further dry-etching or wet-etching the interior of the groove 104 to remove a portion of the gate electrode 71 that is in contact with the inner side surface of the groove 104. With this configuration, the distance (W3) between the gate electrode 70 inside the groove 104 and the inner corners of the groove 104 can be adjusted by removing the gate electrode 71 on the inner side surface of the groove 104, which is in close proximity to the groove 102, to an arbitrary width. That is, W3 can be controlled to an arbitrary length and therefore can be adjusted to an optimum value by comparing the manufacturing cost and resistance to melting.

According to the embodiments described above, the conversion circuit 2201 that includes the semiconductor device manufactured by the manufacturing method described above and that converts input electric power and outputs converted electric power is provided by the method of manufacturing the power converter. Then, the drive circuit 2202 that outputs a drive signal for driving the semiconductor device to the semiconductor device is provided. Then, the control circuit 2203 that outputs a control signal for controlling the drive circuit 2202 to the drive circuit 2202 is provided. With this configuration, when a high voltage is applied, the electric field at the bottom of the groove 104 in the termination area 12 becomes greater than the electric field at the bottoms of the grooves 102 in the cell area 11. Therefore, a breakdown of the gate insulating film 6 is more likely to occur in the termination area 12 and is relatively less likely to occur in the cell area 11 where a large current flows. This suppresses heat generation at a breakdown point, and as a result, suppresses melting of the gate electrode 7.

### Variations of Above-Described Embodiments

In the multiple embodiments described above, the material, composition, dimensions, shape, relative positional relationship, or implementation conditions of each constituent element are described, but these are merely examples in all aspects and are not limiting.

Therefore, numerous modifications and equivalents not shown as examples are assumed to be included within the scope of the technique disclosed in the present specification. Examples of assumed cases include the case of modifying, adding, or omitting at least one constituent element and the case of extracting at least one constituent element in at least one embodiment and combining the extracted constituent element with a constituent element described in another embodiment.

In at least one embodiment described above, when a material name or the like is described without being specifically specified, it is understood that this material may include other additives, such as alloys, unless a contradiction arises.

Furthermore, unless a contradiction arises, when it is stated in the above-described embodiments that “one” constituent element is provided, “one or more” of that constituent element may be provided.

Furthermore, each constituent element in the embodiments described above is a conceptual unit, and the scope of the technique disclosed in the specification of the present application includes cases where one constituent element is made up of multiple structures, where one constituent element corresponds to a part of a structure, and even where multiple constituent elements are provided in one structure.

Furthermore, each constituent element in the embodiments described above includes structures having other structures or shapes as long as the same function is achieved.

Furthermore, the descriptions in the specification of the present application are incorporated by reference for all purposes related to the technique according to the present application, and none of them are admitted to be prior art.

Various aspects of the present disclosure are summarized below as appendices.

### Appendix 1

A semiconductor device includes:
a silicon carbide (SiC) substrate of a first conductivity type;
a drift layer of the first conductivity type formed on an upper surface of the SiC substrate;
a base region of a second conductivity type formed in a surface layer of the drift layer, the second conductivity type being different from the first conductivity type;
at least one first groove formed from an upper surface of the base region to an interior of the drift layer in a cell area;
a second groove formed from the upper surface of the base region to the interior of the drift layer in a termination area that surrounds the cell area in plan view;
a source region of the first conductivity type formed partially in a surface layer of the base region to sandwich the first groove;
a first gate electrode formed inside the first groove and surrounded by a gate insulating film;
at least one second gate electrode formed inside the second groove and surrounded by a gate insulating film;
interlayer insulation films formed to cover the first gate electrode and the second gate electrode;
a source electrode formed in contact with the source region; and a drain electrode formed on a lower surface of the SiC substrate that is a surface on a side opposite to the upper surface of the SiC substrate,
wherein the first gate electrode and the second gate electrode are electrically connected to each other, and
the second groove is deeper than the first groove.

### Appendix 2

In the semiconductor device according to Appendix 1,
the first groove has a narrower width than the second groove in plan view.

### Appendix 3

In the semiconductor device according to Appendix 1 or 2,
90°<α is satisfied, where a is an angle of a corner between bottom and side surfaces of the second groove in the termination area.

### Appendix 4

In the semiconductor device according to any one of Appendices 1 to 3,
the second gate electrode is formed to be spaced from an inner side surface of the second groove. Appendix 5

In the semiconductor device according to Appendix 4,
the second gate electrode includes a spaced gate electrode and a contact gate electrode, the spaced gate electrode being formed to be spaced from the inner side surface of the second groove, the contact gate electrode being formed in contact with the inner side surface of the second groove.

### Appendix 6

In the semiconductor device according to any one of Appendices 1 to 5,
a distance between the interlayer insulation film that is formed to cover the second gate electrode and the interlayer insulation film that is formed to cover the first gate electrode is greater than a distance between the interlayer insulation films that are formed to cover the first gate electrode.

### Appendix 7

In the semiconductor device according to any one of Appendices 1 to 5,
the interlayer insulation film that is formed to cover the first gate electrode located adjacent to the second gate electrode is connected to the interlayer insulation film that is formed to cover the second gate electrode.

### Appendix 8

A power converter includes:
a conversion circuit that includes the semiconductor device according to any one of Appendices 1 to 7 and that converts input electric power and outputs converted electric power;
a drive circuit that outputs a drive signal for driving the semiconductor device to the semiconductor device; and
a control circuit that outputs a control signal for controlling the drive circuit to the drive circuit.

### Appendix 9

A method of manufacturing a semiconductor device, comprising:
forming a drift layer of a first conductivity type on an upper surface of a silicon carbide (SiC) substrate of a first conductivity type;
forming a base region of a second conductivity type in a surface layer of the drift layer, the second conductivity type being different from the first conductivity type;
forming a source region of the first conductivity type partially in a surface layer of the base region;
forming at least one first groove from an upper surface of the source region to an interior of the drift layer in a cell area;
forming a second groove from the upper surface of the source region to the interior of the drift layer in a termination area that surrounds the cell area in plan view;
forming a first gate electrode inside the first groove, the first gate electrode being surrounded by a gate insulating film;
forming at least one second gate electrode inside the second groove, the second gate electrode being surrounded by a gate insulating film;
forming interlayer insulation films to cover the first gate electrode and the second gate electrode;
forming a source electrode in contact with the source region; and
forming a drain electrode on a lower surface of the SiC substrate that is a surface on a side opposite to the upper surface of the SiC substrate;
wherein the first gate electrode and the second gate electrode are electrically connected to each other, and
the second groove is deeper than the first groove.

### Appendix 10

In the method of manufacturing a semiconductor device according to Appendix 9,
forming the first groove corresponds to forming the first groove by using a first mask; and
forming the second groove corresponds to forming the second groove by using a second mask different from the first mask.

### Appendix 11

In the method of manufacturing a semiconductor device according to Appendix 9 or 10,
forming the second gate electrode corresponds to forming the second gate electrode to be spaced from an inner side surface of the second groove, by etching an interior of the second groove.

Appendix 12

In the method of manufacturing a semiconductor device according to Appendix 11,
forming the second gate electrode corresponds to forming the second gate electrode to be spaced from the inner side surface of the second groove, by dry-etching the interior of the second groove and further dry-etching or wet-etching the interior or the second groove to remove a portion of the second gate electrode that is in contact with the inner side surface of the second groove.

### Appendix 13

A method of manufacturing a power converter includes:
providing a conversion circuit that includes the semiconductor device manufactured by the manufacturing method according to any one of Appendices 9 to 12 and that converts input electric power and outputs converted electric power;
providing a drive circuit that outputs a drive signal for driving the semiconductor device to the semiconductor device; and
providing a control circuit that outputs a control signal for controlling the drive circuit to the drive circuit.

### EXPLANATION OF REFERENCE SIGNS

1 SiC substrate
2 drift layer
3 base region
4 source region
5 base region
6 gate insulating film
7 gate electrode
8 interlayer insulation film
9 source electrode
10 drain electrode
11 cell area
12 termination area
13 mask
14 mask
15 mask
15A mask
16 mask
17 mask
18 mask
18A inclined surface
19 mask
70 gate electrode
71 gate electrode
71A gate electrode
72 electrode layer
102 groove
104 groove
104A groove
2100 power supply
2200 power converter
2201 conversion circuit
2202 drive circuit
2203 control circuit
2300 load

1. A semiconductor device comprising:
a silicon carbide (SIC) substrate of a first conductivity type;
a drift layer of the first conductivity type formed on an upper surface of the SiC substrate;
a base region of a second conductivity type formed in a surface layer of the drift layer, the second conductivity type being different from the first conductivity type;
at least one first groove formed from an upper surface of the base region to an interior of the drift layer in a cell area;
a second groove formed from the upper surface of the base region to the interior of the drift layer in a termination area that surrounds the cell area in plan view;
a source region of the first conductivity type formed partially in a surface layer of the base region to sandwich the first groove;
a first gate electrode formed inside the first groove and surrounded by a gate insulating film;
at least one second gate electrode formed inside the second groove and surrounded by a gate insulating film;
interlayer insulation films formed to cover the first gate electrode and the second gate electrode;
a source electrode formed in contact with the source region; and
a drain electrode formed on a lower surface of the SiC substrate that is a surface on a side opposite to the upper surface of the SiC substrate,
wherein the first gate electrode and the second gate electrode are electrically connected to each other,
the second groove is deeper than the first groove, and
a width of the first groove in plan view is narrower than a width of the second groove in plan view.

2. The semiconductor device according to claim 1, further comprising:
the first gate electrode that is in contact with an upper surface of the gate insulating film formed on a bottom surface of the first groove; and
the second gate electrode that is in contact with an upper surface of the gate insulating film formed on a bottom surface of the second groove.

3. The semiconductor device according to claim 1, wherein
90°<α is satisfied, where a is an angle of a corner between bottom and side surfaces of the second groove in the termination area.

4. The semiconductor device according to claim 1, wherein
the second gate electrode is formed to be spaced from an inner side surface of the second groove.

5. The semiconductor device according to claim 4, wherein
the second gate electrode includes a spaced gate electrode and a contact gate electrode, the spaced gate electrode being formed to be spaced from the inner side surface of the second groove, the contact gate electrode being formed in contact with the inner side surface of the second groove.

6. The semiconductor device according to claim 1, wherein
a distance between the interlayer insulation film that is formed to cover the second gate electrode and the interlayer insulation film that is formed to cover the first gate electrode is greater than a distance between the interlayer insulation films that are formed to cover the first gate electrode.

7. The semiconductor device according to claim 1, wherein
the interlayer insulation film that is formed to cover the first gate electrode located adjacent to the second gate electrode is connected to the interlayer insulation film that is formed to cover the second gate electrode.

8. A power converter comprising:
a conversion circuit that includes the semiconductor device according to claim 1 and that converts input electric power and outputs converted electric power;
a drive circuit that outputs a drive signal for driving the semiconductor device to the semiconductor device; and
a control circuit that outputs a control signal for controlling the drive circuit to the drive circuit.

9. A method of manufacturing a semiconductor device, comprising:
forming a drift layer of a first conductivity type on an upper surface of a silicon carbide (SiC) substrate of a first conductivity type;
forming a base region of a second conductivity type in a surface layer of the drift layer, the second conductivity type being different from the first conductivity type;
forming a source region of the first conductivity type partially in a surface layer of the base region;
forming at least one first groove from an upper surface of the source region to an interior of the drift layer in a cell area;
forming a second groove from the upper surface of the source region to the interior of the drift layer in a termination area that surrounds the cell area in plan view;
forming a first gate electrode inside the first groove, the first gate electrode being surrounded by a gate insulating film;
forming at least one second gate electrode inside the second groove, the second gate electrode being surrounded by a gate insulating film;
forming interlayer insulation films to cover the first gate electrode and the second gate electrode;
forming a source electrode in contact with the source region; and
forming a drain electrode on a lower surface of the SIC substrate that is a surface on a side opposite to the upper surface of the SiC substrate;
wherein the first gate electrode and the second gate electrode are electrically connected to each other, and
the second groove is deeper than the first groove, and
a width of the first groove in plan view is narrower than a width of the second groove in plan view.

10. The method of manufacturing a semiconductor device according to claim 9, wherein
forming the first groove corresponds to forming the first groove by using a first mask; and
forming the second groove corresponds to forming the second groove by using a second mask different from the first mask.

11. The method of manufacturing a semiconductor device according to claim 9, wherein
forming the second gate electrode corresponds to forming the second gate electrode to be spaced from an inner side surface of the second groove, by etching an interior of the second groove.

12. The method of manufacturing a semiconductor device according to claim 11, wherein
forming the second gate electrode corresponds to forming the second gate electrode to be spaced from the inner side surface of the second groove, by dry-etching the interior of the second groove and further dry-etching or wet-etching the interior of the second groove to remove a portion of the second gate electrode that is in contact with the inner side surface of the second groove.

13. (canceled)
